(19) United States
(12) Patent Application Publication
(10) Pub. No.: US 2026/0238194 A1
(43) Pub. Date: Aug. 13, 2026

(54) SEMICONDUCTOR DEVICE

(71) Applicant: SEMICONDUCTOR ENERGY LABORATORY CO., LTD., Atsugi-shi, Kanagawa-ken (JP)

(72) Inventors: Kouhei TOYOTAKA, Isehara, Kanagawa (JP); Yuto YAKUBO, Atsugi, Kanagawa (JP); Masashi FUJITA, Fuchu, Tokyo (JP)

(21) Appl. No.: 19/154,820

(22) PCT Filed: Feb. 26, 2024
(86) PCT No.: PCT/IB2024/051794

§ 371 Date: Aug. 8, 2025

(30) Foreign Application Priority Data
Mar. 3, 2023 (JP) 2023-032368

(51) Int. Cl. H03K 3/037; H10D 84/80; H10D 88/00

(52) U.S. Cl. CPC H03K 3/037; H10D 84/813; H10D 88/00

(57) ABSTRACT

A novel semiconductor device is provided. The semiconductor device includes a first circuit, a second circuit, and a third circuit, and the first circuit has a function of outputting a second signal corresponding to an input first signal, in synchronization with a clock signal. The second circuit has a function of retaining a third signal corresponding to the second signal even when power supply is stopped. The third circuit has a function of supplying a signal corresponding to the third signal to the first circuit in accordance with a selection signal. The second circuit includes an OS transistor.

### TECHNICAL FIELD

One embodiment of the present invention relates to a semiconductor device and the like.

Note that one embodiment of the present invention is not limited to the above technical field. The technical field of the invention disclosed in this specification and the like relates to an object, a method, or a manufacturing method. One embodiment of the present invention relates to a process, a machine, manufacture, or a composition of matter. Thus, more specifically, examples of the technical field of one embodiment of the present invention disclosed in this specification include a semiconductor device, a display device, a light-emitting device, a power storage device, a storage device (memory device), a driving method thereof, and a manufacturing method thereof.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. In some cases, a storage device, a display device, a light-emitting device, a lighting device, an electronic device, and the like themselves are semiconductor devices and also include a semiconductor device.

### BACKGROUND ART

The technology development of a semiconductor device that can retain charge corresponding to data by combining a transistor including an oxide semiconductor in a semiconductor layer where a channel is formed (also referred to as an “OS transistor”) and a transistor including silicon in a semiconductor layer where a channel is formed (also referred to as a “Si transistor”) has progressed.

The semiconductor device can achieve low power consumption owing to power gating or the like by having a structure of performing saving (“storing” or “backing up”) or loading (“restoring” or “recovering”) of a program or data retained in a flip-flop or the like. For example, Patent Document 1 discloses a structure in which an OS transistor is connected to a flip-flop that is a volatile storage circuit to achieve a nonvolatile flip-flop.

### REFERENCE

### Patent Document

[Patent Document 1] Japanese Published Patent Application No. 2016-82593

### SUMMARY OF THE INVENTION

### Problems to be Solved by the Invention

An object of one embodiment of the present invention is to provide a novel semiconductor device or the like. Another object is to provide a power-saving semiconductor device or the like. Another object is to provide a semiconductor device or the like that is capable of high-speed operation.

Note that the objects of one embodiment of the present invention are not limited to the objects listed above. The objects listed above do not preclude the existence of other objects. Note that the other objects are objects that are not described in this section and are described below. The objects that are not described in this section will be derived from the description of the specification, the drawings, and the like and can be extracted as appropriate from the description by those skilled in the art. Note that one embodiment of the present invention is to solve at least one of the objects listed above and/or the other objects.

### Means for Solving the Problems

One embodiment of the present invention is a semiconductor device including a first circuit, a second circuit, and a third circuit; the first circuit includes first to fifth inverter circuits and first to fourth switches; the second circuit includes an input portion X and an output portion Y; the third circuit includes an input portion A, an input portion B, and an output portion Z; an output portion of the first inverter circuit is electrically connected to one terminal of the first switch; the other terminal of the first switch is electrically connected to one terminal of the second switch; the other terminal of the second switch is electrically connected to an output portion of the second inverter circuit; an input portion of the second inverter circuit is electrically connected to one terminal of the third switch; the other terminal of the third switch is electrically connected to an input portion of the third inverter circuit and one terminal of the fourth switch; an output portion of the third inverter circuit is electrically connected to an input portion of the fourth inverter circuit and an input portion of the fifth inverter circuit; an output portion of the fourth inverter circuit is electrically connected to the other terminal of the fourth switch; the output portion of the third inverter circuit is electrically connected to the input portion X; the output portion Y is electrically connected to the input portion A; the input portion B is electrically connected to the one terminal of the second switch; and the output portion Z is electrically connected to the one terminal of the third switch.

The second circuit functions as a storage circuit. The second circuit includes a transistor and a capacitor. For example, one of a source and a drain of the transistor functions as the input portion X, and the other of the source and the drain of the transistor functions as the output portion Y. The other of the source and the drain of the transistor is electrically connected to one terminal of the capacitor. The transistor preferably includes an oxide semiconductor in a semiconductor layer where a channel is formed.

The above semiconductor device has a function of supplying, to an output portion of the fifth inverter circuit, a signal corresponding to a signal supplied to an input portion of the first inverter circuit, in synchronization with a clock signal. Each of the first switch and the fourth switch has a function of operating in synchronization with a clock signal, and each of the second switch and the third switch has a function of operating in synchronization with an inverted clock signal.

The third circuit functions as a selection circuit. The third circuit has a function of supplying, to the output portion Z, a signal corresponding to a signal supplied to the input portion A; a function of supplying, to the output portion Z, a signal corresponding to a signal supplied to the input portion B; and a function of determining a signal to be supplied to the output portion Z in accordance with a selection signal.

### Effect of the Invention

According to one embodiment of the present invention, a novel semiconductor device or the like can be provided. Alternatively, a power-saving semiconductor device or the like can be provided. Alternatively, a semiconductor device or the like that is capable of high-speed operation can be provided.

Note that the description of these effects does not preclude the existence of other effects. One embodiment of the present invention does not necessarily have all these effects. Other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1 is a diagram showing a circuit structure of a semiconductor device.

FIG. 2 is a diagram showing a circuit structure of a semiconductor device.

FIG. 3A is a truth table of a third circuit. FIG. 3B is a diagram showing a structure example of the third circuit.

FIG. 4A is a diagram showing circuit symbols of a semiconductor device. FIG. 4B is a timing chart showing an operation of the semiconductor device.

FIG. 5 is a diagram showing a circuit structure of a semiconductor device.

FIG. 6A is a diagram showing circuit symbols of a semiconductor device. FIG. 6B is a timing chart showing an operation of the semiconductor device.

FIG. 7 is a diagram showing a circuit structure of a semiconductor device.

FIG. 8A is a diagram showing circuit symbols of a semiconductor device. FIG. 8B is a timing chart showing an operation of the semiconductor device.

FIG. 9 is a diagram showing a circuit structure of a semiconductor device.

FIG. 10A is a diagram showing an edge detection circuit. FIG. 10B is a timing chart showing an operation of the edge detection circuit.

FIG. 11A and FIG. 11B are diagrams showing a structure example of a semiconductor device.

FIG. 12A is a plan view of a transistor. FIG. 12B and FIG. 12C are cross-sectional views of the transistor.

FIG. 13A is a plan view of a transistor. FIG. 13B and FIG. 13C are cross-sectional views of the transistor.

FIG. 14A is a plan view of a transistor. FIG. 14B and FIG. 14C are cross-sectional views of the transistor.

FIG. 15 is a diagram showing a stacked-layer structure example of a semiconductor device.

FIG. 16 is a block diagram showing a structure example of a semiconductor device.

FIG. 17 is a block diagram showing a CPU.

FIG. 18A and FIG. 18B are perspective views of a semiconductor device.

FIG. 19A and FIG. 19B are perspective views of a semiconductor device.

FIG. 20A and FIG. 20B are diagrams showing hierarchies of a variety of storage devices.

FIG. 21A to FIG. 21J are diagrams showing examples of electronic devices.

FIG. 22A to FIG. 22C are diagrams showing examples of electronic devices.

FIG. 23 is a diagram showing an example of a device for space.

### MODE FOR CARRYING OUT THE INVENTION

Embodiments will be described below with reference to the drawings. However, the embodiments can be implemented with various modes, and it will be readily appreciated by those skilled in the art that modes and details can be changed in various ways without departing from the spirit and scope of the present invention. Thus, the present invention should not be interpreted as being limited to the following description of the embodiments.

In the drawings, the size, the layer thickness, or the region is exaggerated for clarity in some cases. Therefore, the size, the layer thickness, or the region is not limited to the illustrated scale. Note that the drawings schematically illustrate ideal examples, and embodiments of the present invention are not limited to shapes, values, and the like illustrated in the drawings.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, a metal oxide used in an active layer of a transistor is referred to as an oxide semiconductor in some cases. That is, an OS transistor can also be referred to as a transistor including a metal oxide or an oxide semiconductor.

Ordinal numbers such as “first” and “second” in this specification and the like are used in order to avoid confusion among components and do not denote any priority or sequence such as the sequence of steps or the stacking sequence. A term without an ordinal number in this specification and the like may be provided with an ordinal number in the scope of claims in order to avoid confusion among components. An ordinal number provided in this specification and the like and an ordinal number provided in the scope of claims might be different from each other. Furthermore, even when a term is provided with an ordinal number in this specification and the like, the ordinal number might be omitted in the scope of claims and the like.

In this specification and the like, the terms such as “electrode”, “wiring”, and “terminal” do not limit the functions of such components. For example, an “electrode” is used as part of a “wiring” in some cases, and vice versa. Furthermore, the terms “electrode” and “wiring” can also mean that a plurality of “electrodes” and “wirings” are provided in an integrated manner. For example, a “terminal” is used as part of a “wiring” or an “electrode” in some cases, and vice versa. Furthermore, the term “terminal” also includes the case where a plurality of “electrodes”, “wirings”, “terminals”, or the like are formed in an integrated manner, for example. Therefore, for example, an “electrode” can be part of a “wiring” or a “terminal”, and a “terminal” can be part of a “wiring” or an “electrode”. Moreover, terms such as “electrode”, “wiring”, and “terminal” can sometimes be replaced with a term such as “region” depending on the case.

In this specification and the like, a high power supply potential VDD (hereinafter, also simply referred to as “VDD” or “potential H”) is a power supply potential higher than a low power supply potential VSS (hereinafter, also simply referred to as “VSS” or “potential L”). VSS refers to a power supply potential at a potential lower than VDD. In addition, a ground potential GND (hereinafter also simply referred to as “GND”) can be used as VDD or VSS. For example, VSS is a potential lower than GND when VDD is GND, and VDD is a potential higher than GND when VSS is GND.

A “voltage” usually refers to a potential difference between a given potential and a reference potential (e.g., a ground potential or a source potential). A “potential” is a relative value, and a potential supplied to a wiring or the like changes depending on the reference potential in some cases. Therefore, the terms “voltage” and “potential” can be replaced with each other in some cases.

In this specification and the like, supply of a signal refers to supply of a predetermined potential to a wiring or the like. Thus, the term “signal” can be replaced with a term such as “potential” in some cases. A term such as “potential” can be replaced with the term “signal” in some cases. The “signal” may be a variable potential or a fixed potential. For example, it may be a power supply potential.

Note that the terms “film” and “layer” can be used interchangeably depending on the case or the circumstances. For example, the term “conductive layer” can be changed into the term “conductive film” in some cases. As another example, the term “insulating film” can be changed into the term “insulating layer” in some cases.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. The term “capacitor”, “parasitic capacitance”, or “gate capacitance” can be replaced with the term “capacitance” in some cases. Conversely, the term “capacitance” can be replaced with the term “capacitor”, “parasitic capacitance”, or “gate capacitance” in some cases. In addition, a “capacitor” (including a “capacitor” with three or more terminals) includes an insulator and a pair of conductors between which the insulator is interposed. Thus, the term “pair of conductors” of “capacitor” can be replaced with “pair of electrodes”, “pair of conductive regions”, “pair of regions”, or “pair of terminals”. In addition, the term “one of a pair of terminals” is referred to as “one terminal” or a “first terminal” in some cases. The term “the other of the pair of terminals” is referred to as “the other terminal” or a “second terminal” in some cases. Note that the electrostatic capacitance value can be higher than or equal to 0.05 fF and lower than or equal to 10 pF, for example. For another example, the electrostatic capacitance value may be higher than or equal to 1 pF and lower than or equal to 10 μF.

In this specification and the like, a “gate” refers to part or the whole of a gate electrode and a gate wiring. A gate wiring refers to a wiring for electrically connecting at least one gate electrode of a transistor to another electrode or another wiring.

In this specification and the like, a “source” refers to part or the whole of a source region, a source electrode, and a source wiring. A source region refers to a region in a semiconductor layer, where the resistivity is lower than or equal to a given value. A source electrode refers to a conductive layer including a part connected to a source region. A source wiring refers to a wiring for electrically connecting at least one source electrode of a transistor to another electrode or another wiring.

In this specification and the like, a “drain” refers to part or the whole of a drain region, a drain electrode, and a drain wiring. A drain region refers to a region in a semiconductor layer, where the resistivity is lower than or equal to a given value. A drain electrode refers to a conductive layer including a part connected to a drain region. A drain wiring refers to a wiring for electrically connecting at least one drain electrode of a transistor to another electrode or another wiring.

In this specification and the like, the expression “A and B are connected” means the case where A and B are electrically connected as well as the case where A and B are directly connected. Here, the expression “A and B are electrically connected” means the case where electric signals can be transmitted and received between A and B when an object having any electric action is present between A and B.

In this specification and the like, the terms for describing positioning, such as “over”, “under” “above”, and “below”, are sometimes used for convenience to describe the positional relation between components with reference to drawings. The positional relation between components is changed as appropriate in accordance with the direction in which the components are described. Thus, the positional relation is not limited to the terms described in the specification and the like, and can be described with another term as appropriate depending on the situation. For example, the expression “an insulator positioned over (on) a top surface of a conductor” can be replaced with the expression “an insulator positioned under (on) a bottom surface of a conductor” when the direction of a drawing showing these components is rotated by 180°.

Furthermore, the term “over” or “under” does not necessarily mean that a component is placed directly over or directly under and in direct contact with another component. For example, the expression “an electrode B over an insulating layer A” does not necessarily mean that the electrode B is formed over and in direct contact with the insulating layer A, and does not exclude the case where another component is provided between the insulating layer A and the electrode B.

The term “overlap”, for example, in this specification and the like does not limit a state such as the stacking order of components. For example, the expression “the electrode B overlapping with the insulating layer A” does not necessarily mean the state where the electrode B is formed over the insulating layer A, and does not exclude the state where the electrode B is formed under the insulating layer A and the state where the electrode B is formed on the right side (or the left side) of the insulating layer A.

Each of the terms “adjacent” and “proximity” in this specification and the like does not necessarily mean that a component is directly in contact with another component. For example, the expression “the electrode B adjacent to the insulating layer A” does not necessarily mean that the electrode B is formed in direct contact with the insulating layer A and does not exclude the case where another component is provided between the insulating layer A and the electrode B.

In this specification and the like, the terms “identical”, “the same”, “equal”, “uniform”, and the like (including synonyms thereof) used in describing calculation values and measurement values contain an error of ±20 % unless otherwise specified.

In this specification and the like, when a plurality of components are denoted by the same reference numerals, and in particular need to be distinguished from each other, an identification sign such as “A”, “b”, “_1”, “[n]”, or “[m, n]” is sometimes added to the reference numerals. For example, to distinguish a plurality of storage units 255, the terms such as a storage unit 255[1], a storage unit 255[2], and a storage unit 255[3] are used in some cases.

### EMBODIMENT 1

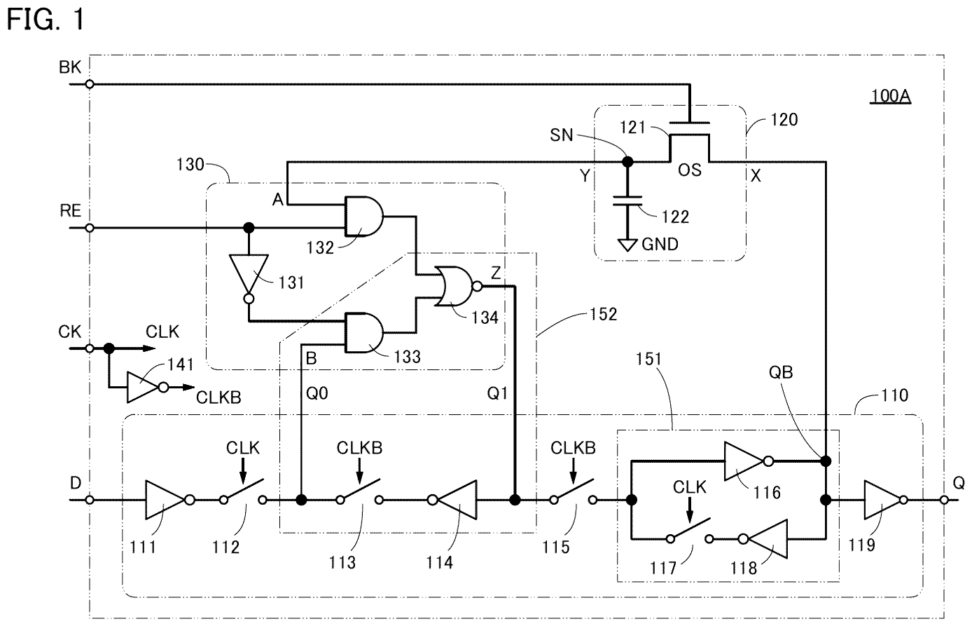

In this embodiment, structure examples of a semiconductor device of one embodiment of the present invention will be described. FIG. 1 is a diagram showing a circuit structure of a semiconductor device 100A.

### <Structure Example>

The semiconductor device 100A includes a terminal D, a terminal CK, a terminal RE, a terminal BK, and a terminal Q. A clock signal CLK is input to the terminal CK. A restore signal (also referred to as a selection signal) is input to the terminal RE. A backup signal is input to the terminal BK. The semiconductor device 100A has a function of storing a value (a potential) of the terminal D when the clock signal CLK input to the terminal CK becomes a potential H and outputting the value from the terminal Q.

The semiconductor device 100A includes a first circuit 110, a second circuit 120, and a third circuit 130. Furthermore, the semiconductor device 100A includes an inverter circuit 141 functioning as an internal clock generation circuit. The inverter circuit 141 has a function of outputting an inverted clock signal CLKB, which is an inverted signal of the input clock signal CLK. Note that a terminal CKB may be provided in the semiconductor device 100A (not shown), and the inverted clock signal CLKB, which is the inverted signal of the clock signal CLK, may be input to the terminal CKB. In that case, the inverter circuit 141 for generating the inverted clock signal CLKB is not necessarily provided.

The first circuit 110 has a function of supplying, to the terminal Q, a signal (also referred to as a second signal) corresponding to a signal (also referred to as a first signal) supplied to the terminal D, in synchronization with the clock signal.

The first circuit 110 includes a first inverter circuit 111, a second inverter circuit 114, a third inverter circuit 116, a fourth inverter circuit 118, a fifth inverter circuit 119, a first switch 112, a second switch 113, a third switch 115, and a fourth switch 117.

An input portion of the first inverter circuit 111 is electrically connected to the terminal D, and an output portion of the first inverter circuit 111 is electrically connected to one terminal of the first switch 112. The other terminal of the first switch 112 is electrically connected to one terminal of the second switch 113. The other terminal of the second switch 113 is electrically connected to an output portion of the second inverter circuit 114. An input portion of the second inverter circuit 114 is electrically connected to one terminal of the third switch 115. The other terminal of the third switch 115 is electrically connected to an input portion of the third inverter circuit 116 and one terminal of the fourth switch 117. An output portion of the third inverter circuit 116 is electrically connected to an input portion of the fourth inverter circuit 118, an input portion of the fifth inverter circuit 119, and one of a source and a drain of a transistor 121. An output portion of the fourth inverter circuit 118 is electrically connected to the other terminal of the fourth switch 117. An output portion of the fifth inverter circuit 119 is electrically connected to the terminal Q.

In each of the first switch 112 and the fourth switch 117, electrical continuity is established (current can flow) between one terminal and the other terminal when the clock signal CLK is the potential H, and electrical continuity is broken between the one terminal and the other terminal when the clock signal CLK is a potential L.

In each of the second switch 113 and the third switch 115, electrical continuity is established between one terminal and the other terminal when the inverted clock signal CLKB is the potential H, and electrical continuity is broken between the one terminal and the other terminal when the inverted clock signal CLKB is the potential L.

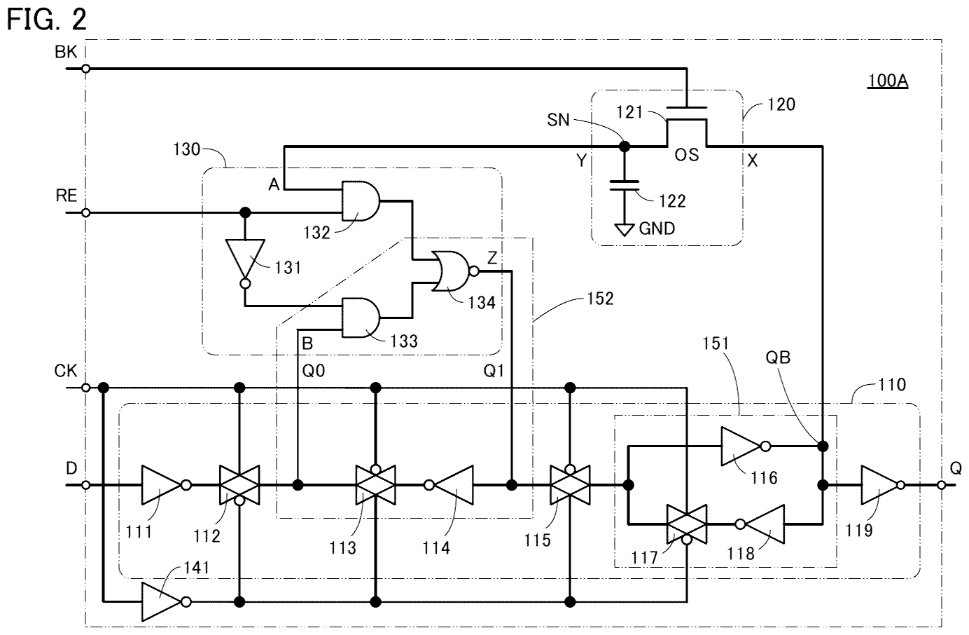

Analog switches may be used as the first switch 112, the second switch 113, the third switch 115, and the fourth switch 117. FIG. 2 shows a circuit structure in the case where analog switches are used as the first switch 112, the second switch 113, the third switch 115, and the fourth switch 117.

OS transistors may be used as the first switch 112, the second switch 113, the third switch 115, and the fourth switch 117. An OS transistor has an extremely low off-state current and a high withstand voltage between a source and a drain. Thus, the OS transistor is suitable as the switch.

The second circuit 120 functions as a storage circuit. The second circuit 120 has a function of retaining a third signal corresponding to the second signal. In the semiconductor device 100A, the third signal is an inverted signal of the second signal and is supplied to the output portion of the third inverter circuit 116.

The second circuit 120 includes the transistor 121 and a capacitor 122. A gate of the transistor 121 is electrically connected to the terminal BK, and the one of the source and the drain of the transistor 121 is electrically connected to the output portion of the third inverter circuit 116, the input portion of the fourth inverter circuit 118, and the input portion of the fifth inverter circuit 119. A region where the one of the source and the drain of the transistor 121, the output portion of the third inverter circuit 116, the input portion of the fourth inverter circuit 118, and the input portion of the fifth inverter circuit 119 are connected to each other and always have the same potential is referred to as a “node QB”.

The other of the source and the drain of the transistor 121 is electrically connected to one terminal (or electrode) of the capacitor 122. In this specification, a region where the other of the source and the drain of the transistor 121 and the one terminal of the capacitor 122 are connected to each other and have the same potential is referred to as a “node SN”.

A ground potential GND is supplied to the other terminal (or electrode) of the capacitor 122. Although a potential supplied to the other terminal of the capacitor 122 may be a variable potential, a fixed potential is preferable. The potential supplied to the other terminal of the capacitor 122 is not limited to the ground potential GND. The potential supplied to the other terminal of the capacitor 122 may be a reference potential (0 V), a high power supply potential VDD, a low power supply potential VSS, or the like.

In the second circuit 120, the one of the source and the drain of the transistor 121 is referred to as an input portion X in some cases. In the second circuit 120, the other of the source and the drain of the transistor 121 is referred to as an output portion Y in some cases.

Although a Si transistor may be used as the transistor 121, an OS transistor is preferably used. Since the OS transistor has an extremely low off-state current, the amount of charge retained in the node SN is less likely to change. Accordingly, charge supplied to the node SN can be retained for a long time. In addition, electric power for retaining data (charge) written to the node SN is hardly needed. Thus, the second circuit 120 can be regarded as a nonvolatile memory. Furthermore, the second circuit 120 rewrites data by charging and discharging the capacitor 122; hence, there is no limitation on the number of rewriting operations in principle. In addition, data can be written and read at high speed with low energy.

A storage circuit formed using an OS transistor is also referred to as an “OS memory”. Thus, the second circuit 120 is an OS memory.

Note that a transistor including a back gate may be used as the transistor 121. Adjusting a potential supplied to the back gate can control the threshold voltage of the transistor.

The third circuit 130 functions as a selection circuit. The third circuit 130 includes an inverter circuit 131, a first AND circuit 132, a second AND circuit 133, and a NOR circuit 134. The first AND circuit 132, the second AND circuit 133, and the NOR circuit 134 are each a two-input one-output logic circuit.

A first input portion of the first AND circuit 132 is electrically connected to the one terminal of the capacitor 122 and the other of the source and the drain of the transistor 121. Thus, the first input portion of the first AND circuit 132 is electrically connected to the node SN. A second input portion of the first AND circuit 132 is electrically connected to an input portion of the inverter circuit 131 and the terminal RE. An output portion of the first AND circuit 132 is electrically connected to a first input portion of the NOR circuit 134.

An output portion of the inverter circuit 131 is electrically connected to a first input portion of the second AND circuit 133. A second input portion of the second AND circuit 133 is electrically connected to the other terminal of the first switch 112 and the one terminal of the second switch 113. A region where the second input portion of the second AND circuit 133, the other terminal of the first switch 112, and the one terminal of the second switch 113 are connected to each other and always have the same potential is referred to as a “node Q0”.

An output portion of the second AND circuit 133 is electrically connected to a second input portion of the NOR circuit 134. An output portion of the NOR circuit 134 is electrically connected to the input portion of the second inverter circuit 114 and the one terminal of the third switch 115. A region where the output portion of the NOR circuit 134, the input portion of the second inverter circuit 114, and the one terminal of the third switch 115 are connected to each other and always have the same potential is referred to as a “node Q1”.

In the case where the potential H is supplied to the terminal RE, the first AND circuit 132 outputs a potential of the first input portion. That is, in the case where the potential H is supplied to the terminal RE, a potential corresponding to a potential of the node SN is output. In the case where the potential L is supplied to the terminal RE, the first AND circuit 132 always outputs the potential L.

In the case where the potential L is supplied to the terminal RE, the second AND circuit 133 outputs a potential of the second input portion. That is, in the case where the potential L is supplied to the terminal RE, a potential corresponding to a potential of the node Q0 is output. In the case where the potential H is supplied to the terminal RE, the second AND circuit 133 always outputs the potential L.

By the above operations of the first AND circuit 132 and the second AND circuit 133, the potential L is always supplied to one of the first input portion and the second input portion of the NOR circuit 134. Accordingly, an inverted potential of a potential supplied to the other of the first input portion and the second input portion is output from the NOR circuit 134.

In the third circuit 130, the first input portion of the first AND circuit 132 is referred to as an input portion A in some cases. In the third circuit 130, the second input portion of the second AND circuit 133 is referred to as an input portion B in some cases. In the third circuit 130, the output portion of the NOR circuit 134 is also referred to as an output portion Z in some cases.

The third circuit 130 has a function of supplying, to the output portion Z, a signal corresponding to a signal supplied to the input portion A and a function of supplying, to the output portion Z, a signal corresponding to a signal supplied to the input portion B. The signal supplied to the output portion Z is determined in accordance with a selection signal input to the terminal RE.

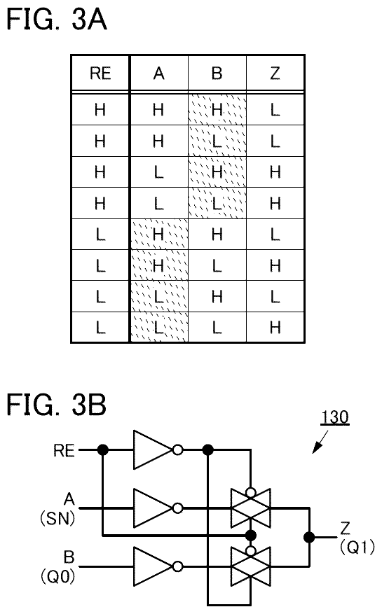

A truth table of the third circuit 130 is shown in FIG. 3A. In the case where the potential H is supplied to the terminal RE as a selection signal, the third circuit 130 outputs an inverted potential of the input portion A to the output portion Z. In the case where the potential L is supplied to the terminal RE as a selection signal, an inverted potential of the input portion B is output to the output portion Z. Note that a potential of the input portion A is the potential of the node SN, a potential of the input portion B is the potential of the node Q0, and a potential of the output portion Z is a potential of the node Q1.

The structure of the third circuit 130 is not limited to the above structure. For example, as shown in FIG. 3B, a structure using an inverter circuit and an analog switch can be employed.

Note that in the first circuit 110, the third inverter circuit 116, the fourth inverter circuit 118, and the fourth switch 117 function as a latch circuit 151. In the case where the potential L is supplied to the terminal RE, the second AND circuit 133 and the NOR circuit 134 function as one inverter circuit. In this case, the second AND circuit 133, the NOR circuit 134, the second inverter circuit 114, and the second switch 113 function as a latch circuit 152. Thus, the semiconductor device 100A functions as a D flip-flop circuit including two latch circuits. The semiconductor device 100A is also a D flip-flop circuit with a backup function.

### <Operation Example>

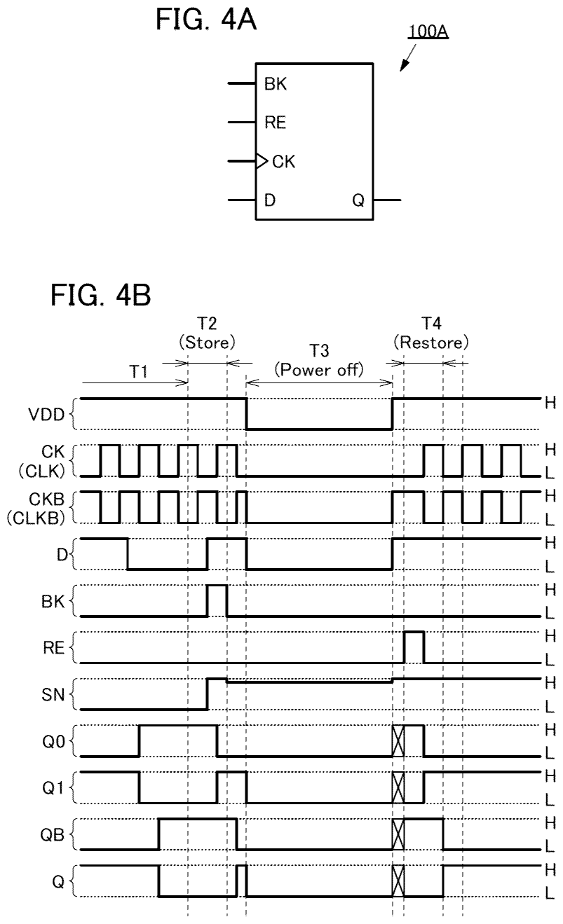

The semiconductor device 100A functions as a storage device capable of retaining written data even when power supply is stopped. Next, an operation example of the semiconductor device 100A will be described. FIG. 4A shows circuit symbols of the semiconductor device 100A. FIG. 4B is a timing chart showing operations of the semiconductor device 100A.

### [Period T1]

Period T1 is a normal operation period. In the normal operation period, when a potential supplied to the terminal D changes, a potential supplied to the terminal Q changes in synchronization with the clock signal CLK and the inverted clock signal CLKB.

Specifically, immediately after the potential supplied to the terminal D changes from the potential H to the potential L, the potential of the node Q0 becomes the potential H and the potential of the node Q1 becomes the potential L at a timing where a potential supplied to the terminal CK (the clock signal CLK) changes from the potential L to the potential H. Next, at a timing where a potential supplied to the terminal CKB (the inverted clock signal CLKB) changes from the potential L to the potential H, a potential of the node QB becomes the potential H and a potential of the terminal Q becomes the potential L.

### [Period T2]

Before the stop of power supply in Period T3, an operation for retaining the potential supplied to the terminal Q is performed in Period T2. Specifically, the potential of the node QB is retained in the node SN. Period T2 is a period in which data storing operation (Store) is performed. FIG. 4B shows the case where the potential L is supplied to the terminal Q in Period T2.

In Period T2, when the potential H is supplied to the terminal BK, the transistor 121 is brought into an on state, and the node QB and the node SN are electrically connected to each other. Thus, the output of the third inverter circuit 116 is supplied to the node SN through the transistor 121.

Then, the potential L is supplied to the terminal BK and the transistor 121 is brought into an off state, whereby the potential (charge) written to the node SN is retained.

### [Period T3]

Period T3 is a period in which power gating is performed. Specifically, power supply to the semiconductor device 100A is stopped in Period T3 (Power off). When power supply to the semiconductor device 100A is stopped, the potentials of the node Q0, the node Q1, the node QB, and a node Q each become the potential L. Meanwhile, the potential of the node SN is retained even in Period T3 during which power supply is stopped.

In Period T3, supply of the clock signal CLK can also be stopped. When the supply of the clock signal CLK is stopped, generation of the inverted clock signal CLKB inside the semiconductor device 100A is also stopped. Providing Period T3 can reduce power consumption of the semiconductor device 100A.

### [Period T4]

Period T4 is a period in which data restoration operation (Restore) is performed. Specifically, in Period T4, an operation for returning the potential supplied to the terminal Q to a state immediately before the power gating (Period T3) is performed. Before Period T4, power supply to the semiconductor device 100A and supply of the clock signal CLK are restarted. Note that the potentials of the node Q0, the node Q1, the node QB, and the node Q are not fixed immediately after the power supply. Thus, the potential supplied to the terminal Q is also not fixed.

After power supply to the semiconductor device 100A is restarted, in Period T4, the potential H is supplied to the terminal RE when the inverted clock signal CLKB is the potential H (the clock signal CLK is the potential L). When the inverted clock signal CLKB is the potential H (the clock signal CLK is the potential L), the potential H is supplied to the terminal RE, so that electrical continuity is broken between the terminal D and the node Q0.

When the potential H is supplied to the terminal RE, an inverted potential of the node SN is supplied to the node Q1. In this embodiment, the potential H is retained in the node SN, so that the potential L is supplied to the node Q1. Since the inverted clock signal CLKB is the potential H, the potential H is supplied from the second inverter circuit 114 to the node Q0. The potential L is supplied to the input portion of the third inverter circuit 116, and the potential H is supplied from the third inverter circuit 116 to the node QB. Furthermore, the potential L is supplied from the fifth inverter circuit 119 to the terminal Q.

In this manner, the semiconductor device 100A can make the potential supplied to the terminal Q return to the state immediately before the power gating (Period T3). In the semiconductor device 100A of one embodiment of the present invention, Period T4 can be completed in one clock cycle. Thus, it is possible to complete the process from the restart of power supply to data restoration in an extremely short amount of time. The semiconductor device 100A of one embodiment of the present invention can achieve both power saving by power gating and high-speed restoration from power gating.

### MODIFICATION EXAMPLE 1

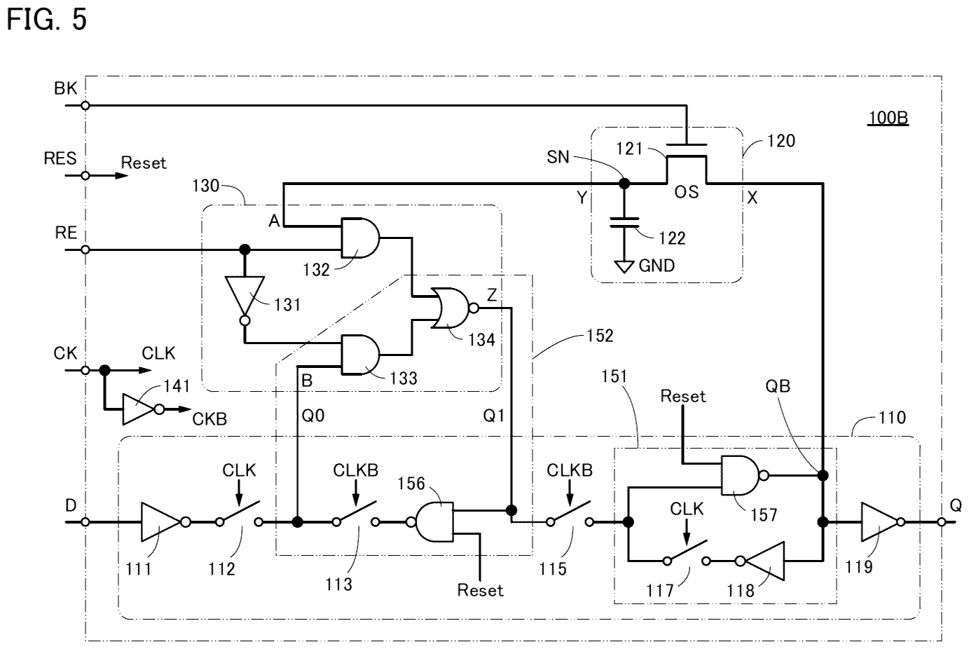

FIG. 5 shows a circuit structure of a semiconductor device 100B, which is a modification example of the semiconductor device 100A. The semiconductor device 100B is the semiconductor device 100A capable of executing a reset operation. That is, the semiconductor device 100B is the semiconductor device 100A to which a reset function is added. The semiconductor device 100B includes a terminal RES, and a reset signal Reset is supplied to the terminal RES. The semiconductor device 100B has a structure in which the second inverter circuit 114 of the semiconductor device 100A and the third inverter circuit 116 of the semiconductor device 100A are replaced with a NAND circuit 156 and a NAND circuit 157, respectively. The NAND circuit 156 and the NAND circuit 157 are each a two-input one-output NAND circuit.

In the semiconductor device 100B, a first input portion of the NAND circuit 156 is electrically connected to the output portion of the NOR circuit 134 and the one terminal of the third switch 115. A second input portion of the NAND circuit 156 is electrically connected to the terminal RES. Thus, the reset signal Reset is supplied to the second input portion of the NAND circuit 156. An output portion of the NAND circuit 156 is electrically connected to the other terminal of the second switch 113. In the semiconductor device 100B, a region electrically connected to the first input portion of the NAND circuit 156, the output portion of the NOR circuit 134, and the one terminal of the third switch 115 is referred to as the node Q1.

In the semiconductor device 100B, a first input portion of the NAND circuit 157 is electrically connected to the terminal RES. Thus, the reset signal Reset is supplied to the first input portion of the NAND circuit 157. A second input portion of the NAND circuit 157 is electrically connected to the other terminal of the third switch 115 and the one terminal of the fourth switch 117. An output portion of the NAND circuit 157 is electrically connected to the input portion of the fourth inverter circuit 118, the input portion of the fifth inverter circuit 119, and the one of the source and the drain of the transistor 121. In the semiconductor device 100B, a region electrically connected to the output portion of the NAND circuit 157, the input portion of the fourth inverter circuit 118, the input portion of the fifth inverter circuit 119, and the one of the source and the drain of the transistor 121 is referred to as the node QB.

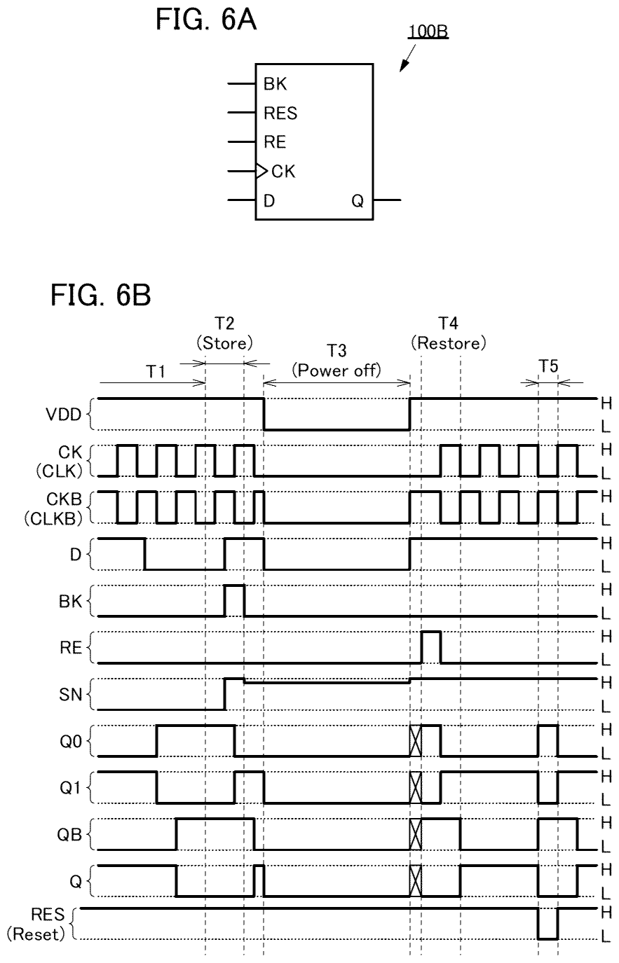

FIG. 6A shows circuit symbols of the semiconductor device 100B. FIG. 6B is a timing chart showing operations of the semiconductor device 100B. FIG. 6B is a timing chart in which the reset operation is executed in Period T5.

When the reset signal Reset is the potential H, the NAND circuit 156 outputs an inverted potential of a potential supplied to the first input portion. When the reset signal Reset is the potential H, the NAND circuit 157 outputs an inverted potential of a potential supplied to the second input portion. Thus, the NAND circuit 156 and the NAND circuit 157 function as an inverter circuit when the reset signal Reset is the potential H. When the reset signal Reset is the potential L, the NAND circuit 156 and the NAND circuit 157 always output the potential H.

The output of the NAND circuit 157 is supplied to the terminal Q through the fifth inverter circuit 119. Thus, when the potential L is supplied as the reset signal Reset to the terminal RES of the semiconductor device 100B, the potential supplied to the terminal Q can be the potential L regardless of the potentials supplied to the terminal D and the terminal CK.

### MODIFICATION EXAMPLE 2

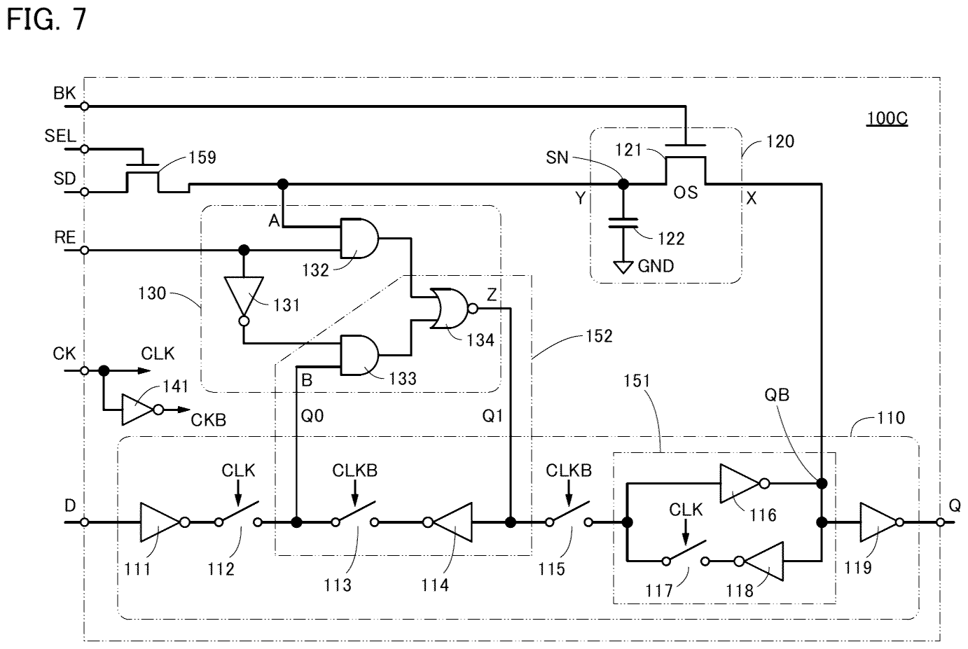

FIG. 7 shows a circuit structure of a semiconductor device 100C, which is a modification example of the semiconductor device 100A. The semiconductor device 100C is the semiconductor device 100A capable of executing a scan operation. That is, the semiconductor device 100C is the semiconductor device 100A to which a scan function for checking an operation is added. The semiconductor device 100C includes a terminal SEL and a terminal SD. An inspection signal is supplied to the terminal SD. The semiconductor device 100C includes a transistor 159. A gate of the transistor 159 is electrically connected to the terminal SEL, and one of a source and a drain of the transistor 159 is electrically connected to the terminal SD. The other of the source and the drain of the transistor 159 is electrically connected to the first input portion of the first AND circuit 132, the one terminal of the capacitor 122, and the other of the source and the drain of the transistor 121.

In the semiconductor device 100C, a region electrically connected to the other of the source and the drain of the transistor 159, the first input portion of the first AND circuit 132, the one terminal of the capacitor 122, and the other of the source and the drain of the transistor 121 is referred to as the node SN.

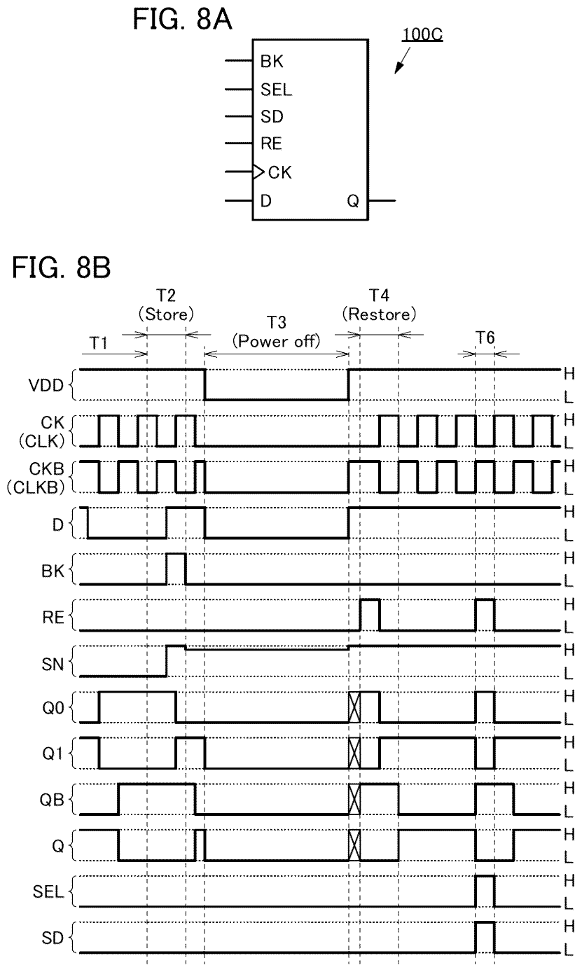

FIG. 8A shows circuit symbols of the semiconductor device 100C. FIG. 8B is a timing chart showing operations of the semiconductor device 100C. FIG. 8B is a timing chart in which the scan operation is executed in Period T6.

The operation of the semiconductor device 100C is checked as follows. First, when the transistor 121 is in an off state with the potential L is supplied to the terminal BK and the inverted clock signal CLKB is the potential H, the potential H is supplied to the terminal RE. The potential H is supplied to the terminal SEL, so that the transistor 159 is brought into an on state. An inspection signal supplied to the terminal SD is supplied to the node SN through the transistor 159.

For example, the potential H is supplied to the terminal SD as an inspection signal. Accordingly, the potential L is supplied to the node Q1, and the potential H is supplied to the node Q0. Furthermore, the potential H is supplied to the node QB, and the potential L is supplied to the terminal Q. In the case where the operation of the semiconductor device 100C is normal, the potential of the terminal Q becomes the potential H when the potential L is supplied as the inspection signal to the node SN, and the potential of the terminal Q becomes the potential L when the potential H is supplied as the inspection signal to the node SN. When the potential H or the potential L is supplied as the inspection signal and the potential that is the inspection signal is compared with the potential supplied to the terminal Q, whether the semiconductor device 100C operates correctly can be checked.

### MODIFICATION EXAMPLE 3

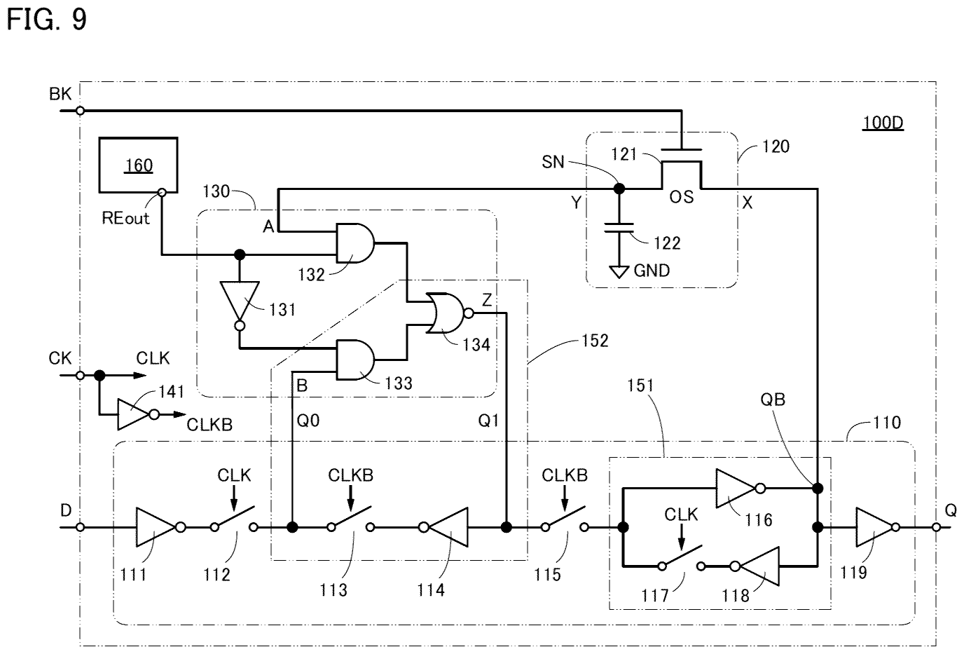

FIG. 9 shows a circuit structure of a semiconductor device 100D, which is a modification example of the semiconductor device 100A. The semiconductor device 100C has a structure in which the terminal RE is removed from the semiconductor device 100A and an edge detection circuit 160 is added.

The edge detection circuit 160 includes a terminal REout. The terminal REout is electrically connected to the second input portion of the first AND circuit 132 and the input portion of the inverter circuit 131.

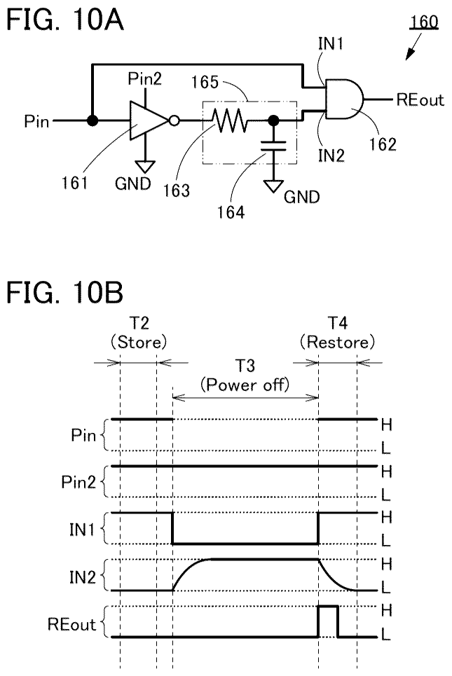

FIG. 10A shows a circuit structure applicable to the edge detection circuit 160. The edge detection circuit 160 shown in FIG. 10A includes an inverter circuit 161, an AND circuit 162, a resistor 163, and a capacitor 164. An input portion of the inverter circuit 161 is electrically connected to a terminal Pin and a first input portion IN1 of the AND circuit 162. VDD (the potential H) is supplied to the input portion of the inverter circuit 161 and the first input portion IN1 of the AND circuit 162 through the terminal Pin. An output portion of the inverter circuit 161 is electrically connected to one terminal of the resistor 163. The other terminal of the resistor 163 is electrically connected to one terminal (or electrode) of the capacitor 164 and a second input portion IN2 of the AND circuit 162. An output portion of the AND circuit 162 is electrically connected to the terminal REout.

The resistor 163 and the capacitor 164 form a delay circuit 165. Thus, the output portion of the inverter circuit 161 and the second input portion IN2 of the AND circuit 162 are connected to each other through the delay circuit 165. As a power source of the inverter circuit 161, the high power supply potential VDD (the potential H) is supplied to the inverter circuit 161 through a terminal Pin2.

FIG. 10B is a timing chart showing an operation of the edge detection circuit 160. In Period T3, each of the potentials of the input portion of the inverter circuit 161 and the first input portion INI become the potential L in conjunction with the stop of power supply to the terminal Pin (the stop of VDD supply). Note that power supply to the inverter circuit 161 is not stopped even in Period T3. That is, since VDD is continuously supplied to the inverter circuit 161 through the terminal Pin2, the potential H is supplied to the output portion of the inverter circuit 161. Since the output portion of the inverter circuit 161 and the second input portion IN2 of the AND circuit 162 are connected to each other through the delay circuit 165, after power supply is stopped, a potential supplied to the second input portion IN2 gradually changes from the potential L to the potential H.

When Period T3 ends and power supply is restarted (Period T4), the potential H is supplied to the input portion of the inverter circuit 161 and the first input portion IN1, and the potential L is supplied to the output portion of the inverter circuit 161. As described above, the output portion of the inverter circuit 161 and the second input portion IN2 of the AND circuit 162 are connected to each other through the delay circuit 165. Accordingly, the potential supplied to the second input portion IN2 gradually changes from the potential H to the potential L. Thus, the potential H is supplied from the output portion of the AND circuit 162 immediately after the start of Period T4, and the potential L is supplied from the output portion of the AND circuit 162 after a certain period of time.

When the edge detection circuit 160 is provided, the terminal RE can be omitted; thus, the number of terminals necessary for the operation can be smaller in the semiconductor device 100D than in the semiconductor device 100A. Accordingly, the number of types of signals necessary for the operation are reduced, so that a semiconductor device with high controllability can be achieved.

### <Stacked-layer Structure Example>

Although circuits, transistors, and the like included in the semiconductor device 100 (the semiconductor device 100A, the semiconductor device 100B, the semiconductor device 100C, and the semiconductor device 100D) may be provided on the same plane, at least some of them are preferably provided to overlap with each other.

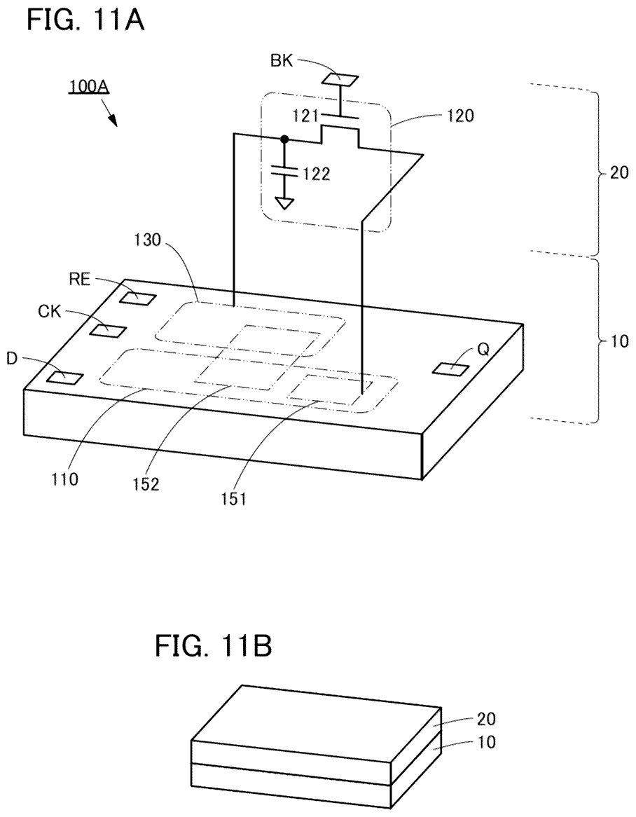

For example, FIG. 11A and FIG. 11B show a structure example of the semiconductor device 100A in which the first circuit 110 and the third circuit 130 are formed in a layer 10 including Si transistors and the second circuit 120 is provided in a layer 20 including OS transistors over the layer 10. When the second circuit 120 is provided above the first circuit 110 and the third circuit 130 to overlap therewith, the area occupied by the semiconductor device 100A can be reduced.

For example, the first circuit 110 and the third circuit 130 included in the semiconductor device 100A can be formed using CMOS circuits using Si transistors, and the second circuit 120 included in the semiconductor device 100A can include OS transistors. In the case where one or more of the first switch 112, the second switch 113, the third switch 115, and the fourth switch 117 are formed using OS transistors, the switch can be provided in the layer 20. Providing the switch in the layer 20 can reduce the area occupied by the semiconductor device 100A.

Note that OS transistors may be used as one or more of the transistors included in the above-described first circuit 110, the third circuit 130, and the edge detection circuit 160.

The structure described in this embodiment can be used in an appropriate combination with the structures described in the other embodiments.

### EMBODIMENT 2

In this embodiment, a structure example of an OS transistor that can be used in the semiconductor device of one embodiment of the present invention will be described.

### <Structure Example 1 of Transistor>

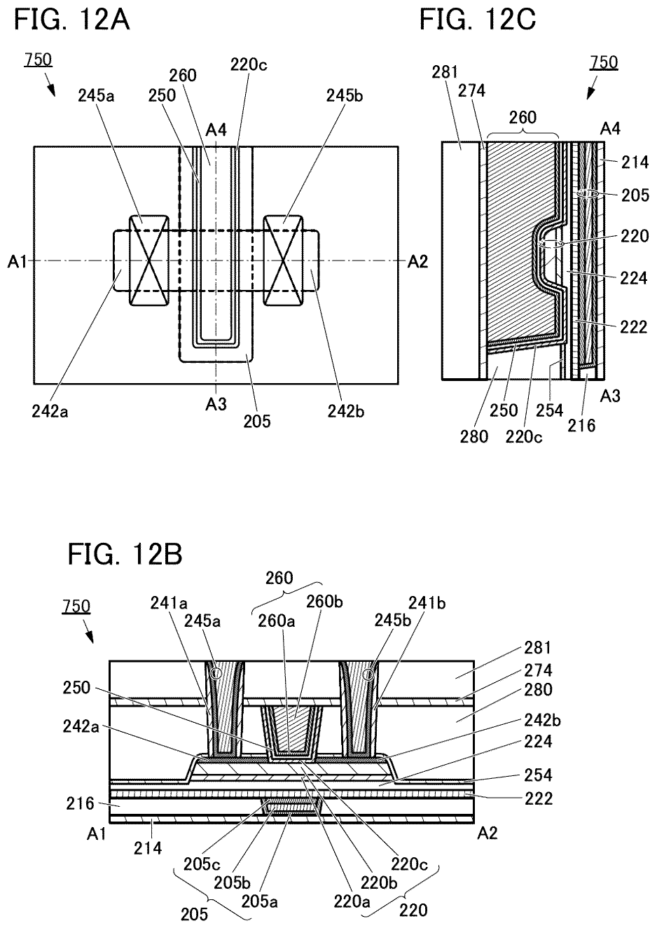

FIG. 12A, FIG. 12B, and FIG. 12C are a plan view and cross-sectional views of a transistor 750 that can be used in the semiconductor device of one embodiment of the present invention. The transistor 750 can be used as the transistor 121, for example. The transistor 750 may be used for part of the first circuit 110, the third circuit 130, and the edge detection circuit 160 FIG. 12A is the plan view of the transistor 750. FIG. 12B and FIG. 12C are cross-sectional views of the transistor 750. Here, FIG. 12B is a cross-sectional view taken along dashed-dotted line A1-A2 in FIG. 12A, which corresponds to a cross-sectional view of the transistor 750 in the channel length direction. FIG. 12C is a cross-sectional view taken along the dashed-dotted line A3-A4 in FIG. 12A, which corresponds to a cross-sectional view of the transistor 750 in the channel width direction. Note that some components are not shown in the plan view in FIG. 12A for clarity of the drawing.

As shown in FIG. 12A to FIG. 12C, the transistor 750 includes a metal oxide 220a placed over a substrate (not shown); a metal oxide 220b placed over the metal oxide 220a; a conductive layer 242a and a conductive layer 242b that are placed apart from each other over the metal oxide 220b; an insulating layer 280 that is placed over the conductive layer 242a and the conductive layer 242b and has an opening formed between the conductive layer 242a and the conductive layer 242b; a conductive layer 260 placed in the opening; an insulating layer 250 placed between the conductive layer 260 and the metal oxide 220b, the conductive layer 242a, the conductive layer 242b, and the insulating layer 280; and a metal oxide 220c placed between the insulating layer 250 and the metal oxide 220b, the conductive layer 242a, the conductive layer 242b, and the insulating layer 280. Here, it is preferable that the top surface of the conductive layer 260 be substantially level with the top surfaces of the insulating layer 250, an insulating layer 254, the metal oxide 220c, and the insulating layer 280 as shown in FIG. 12B and FIG. 12C. Hereinafter, the metal oxide 220a, the metal oxide 220b, and the metal oxide 220c may be collectively referred to as a metal oxide 220. The conductive layer 242a and the conductive layer 242b may be collectively referred to as a conductive layer 242.

As shown in FIG. 12A to FIG. 12C, the insulating layer 254 is preferably placed between the insulating layer 280 and an insulating layer 224, the metal oxide 220a, the metal oxide 220b, the conductive layer 242a, the conductive layer 242b, and the metal oxide 220c. Here, as shown in FIG. 12B and FIG. 12C, the insulating layer 254 is preferably in contact with the side surface of the metal oxide 220c, the top surface and the side surface of the conductive layer 242a, the top surface and the side surface of the conductive layer 242b, the side surfaces of the metal oxide 220a and the metal oxide 220b, and the top surface of the insulating layer 224.

In the transistor 750, three layers of the metal oxide 220a, the metal oxide 220b, and the metal oxide 220c are stacked in and around a region where the channel is formed (hereinafter also referred to as a channel formation region); however, the present invention is not limited thereto. For example, a two-layer structure of the metal oxide 220b and the metal oxide 220c or a stacked-layer structure of four or more layers may be employed. Alternatively, each of the metal oxide 220a, the metal oxide 220b, and the metal oxide 220c may have a stacked-layer structure of two or more layers.

For example, in the case where the metal oxide 220c has a stacked-layer structure including a first metal oxide and a second metal oxide over the first metal oxide, the first metal oxide preferably has a composition similar to that of the metal oxide 220b and the second metal oxide preferably has a composition similar to that of the metal oxide 220a.

Here, the conductive layer 260 functions as a gate electrode of the transistor, and the conductive layer 242a and the conductive layer 242b function as a source electrode and a drain electrode. As described above, the conductive layer 260 is formed to be embedded in the opening of the insulating layer 280 and a region sandwiched between the conductive layer 242a and the conductive layer 242b. Here, the positions of the conductive layer 260, the conductive layer 242a, and the conductive layer 242b with respect to the opening of the insulating layer 280 are selected in a self-aligned manner. That is, in the transistor 750, the gate electrode can be placed between the source electrode and the drain electrode in a self-aligned manner. Thus, the conductive layer 260 can be formed without an alignment margin, resulting in a reduction in the area occupied by the transistor 750. Thus, the area occupied by the semiconductor device can be reduced. In addition, the degree of integration of the semiconductor device can be increased.

As shown in FIG. 12A to FIG. 12C, the conductive layer 260 preferably includes a conductive layer 260a provided on the inner side of the insulating layer 250 and a conductive layer 260b provided to be embedded on the inner side of the conductive layer 260a. Although the conductive layer 260 has a stacked-layer structure of two layers in the transistor 750, the present invention is not limited thereto. For example, the conductive layer 260 may have a single-layer structure or a stacked-layer structure of three or more layers.

The transistor 750 preferably includes an insulating layer 214 placed over the substrate (not shown); an insulating layer 216 placed over the insulating layer 214; a conductive layer 205 placed to be embedded in the insulating layer 216; an insulating layer 222 placed over the insulating layer 216 and the conductive layer 205; and the insulating layer 224 placed over the insulating layer 222. The metal oxide 220a is preferably placed over the insulating layer 224.

An insulating layer 274 and an insulating layer 281 functioning as interlayer films are preferably placed over the transistor 750. Here, the insulating layer 274 is preferably placed in contact with the top surfaces of the conductive layer 260, the insulating layer 250, the insulating layer 254, the metal oxide 220c, and the insulating layer 280.

The insulating layer 222, the insulating layer 254, and the insulating layer 274 preferably have a function of inhibiting diffusion of hydrogen (e.g., at least one of a hydrogen atom and a hydrogen molecule). For example, the insulating layer 222, the insulating layer 254, and the insulating layer 274 preferably have lower hydrogen permeability than the insulating layer 224, the insulating layer 250, and the insulating layer 280. Moreover, the insulating layer 222 and the insulating layer 254 preferably have a function of inhibiting diffusion of oxygen (e.g., at least one of an oxygen atom and an oxygen molecule). For example, the insulating layer 222 and the insulating layer 254 preferably have lower oxygen permeability than the insulating layer 224, the insulating layer 250, and the insulating layer 280.

Here, the insulating layer 224, the metal oxide 220, and the insulating layer 250 are separated by the insulating layer 222 and the insulating layer 274. This can inhibit entry of excess oxygen and impurities such as hydrogen contained in layers above the insulating layer 274 and layers below the insulating layer 222 into the insulating layer 224, the metal oxide 220, and the insulating layer 250.

A conductive layer 245 (a conductive layer 245a and a conductive layer 245b) that is electrically connected to the transistor 750 and functions as a plug is preferably provided. Note that an insulating layer 241 (an insulating layer 241a and an insulating layer 241b) is provided in contact with the side surface of the conductive layer 245 functioning as a plug. In other words, the insulating layer 241 is provided in contact with the inner wall of an opening in the insulating layer 254, the insulating layer 280, the insulating layer 274, and the insulating layer 281. A structure may be employed in which a first conductive layer of the conductive layer 245 is provided in contact with the side surface of the insulating layer 241 and a second conductive layer of the conductive layer 245 is provided on the inner side of the first conductive layer. Here, the top surface of the conductive layer 245 and the top surface of the insulating layer 281 can be substantially level with each other. Although the first conductive layer of the conductive layer 245 and the second conductive layer of the conductive layer 245 are stacked in the transistor 750, the present invention is not limited thereto. For example, the conductive layer 245 may have a single-layer structure or a stacked-layer structure of three or more layers. In the case where a component has a stacked-layer structure, layers may be distinguished by ordinal numbers corresponding to the formation order.

In the transistor 750, a metal oxide functioning as an oxide semiconductor (hereinafter also referred to as an oxide semiconductor) is preferably used for the metal oxide 220 including the channel formation region (the metal oxide 220a, the metal oxide 220b, and the metal oxide 220c). For example, it is preferable to use a metal oxide having a band gap of 2 eV or more, preferably 2.5 eV or more as the metal oxide to be the channel formation region of the metal oxide 220.

The metal oxide preferably contains at least indium (In) or zinc (Zn). In particular, indium (In) and zinc (Zn) are preferably contained. In addition to them, an element M is preferably contained. As the element M, one or more of aluminum (Al), gallium (Ga), yttrium (Y), tin (Sn), boron (B), titanium (Ti), iron (Fe), nickel (Ni), germanium (Ge), zirconium (Zr), molybdenum (Mo), lanthanum (La), cerium (Ce), neodymium (Nd), hafnium (Hf), tantalum (Ta), tungsten (W), magnesium (Mg), and cobalt (Co) can be used. In particular, the element M is preferably one or more of aluminum (Al), gallium (Ga), yttrium (Y), and tin (Sn). The element M further preferably contains one or both of Ga and Sn.

For example, as the metal oxide that can be used for a semiconductor layer of an OS transistor, it is possible to use indium oxide (In oxide), indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide, also referred to as “IGTO”), gallium zinc oxide (Ga—Zn oxide, also referred to as “GZO”), aluminum zinc oxide (Al—Zn oxide, also referred to as “AZO”), indium aluminum zinc oxide (In—Al—Zn oxide, also referred to as “IAZO”), indium tin zinc oxide (In-Sn-Zn oxide), indium titanium zinc oxide (In—Ti—Zn oxide), indium gallium zinc oxide (In—Ga—Zn oxide, also referred to as “IGZO”), indium gallium tin zinc oxide (In—Ga—Sn—Zn oxide, also referred to as “IGZTO”), or indium gallium aluminum zinc oxide (In—Ga—Al—Zn oxide, also referred to as “IGAZO” or “IAGZO”). Alternatively, it is possible to use indium tin oxide containing silicon, gallium tin oxide (Ga—Sn oxide), aluminum tin oxide (Al—Sn oxide), or the like.

By increasing the proportion of the number of indium atoms in the total number of atoms of all the metal elements contained in the metal oxide, the field-effect mobility of the transistor can be increased.

By increasing the proportion of the number of zinc atoms in the total number of atoms of metal elements in the main constituent elements contained in the metal oxide, the metal oxide has high crystallinity, so that diffusion of impurities in the metal oxide can be inhibited. Consequently, a change in electrical characteristics of the transistor can be inhibited, and the reliability of the transistor can be increased.

By increasing the proportion of the number of atoms of the element M in the total number of atoms of metal elements in the main constituent elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be improved.

Electrical characteristics and reliability of a transistor depend on the composition of the metal oxide used for the semiconductor layer. Therefore, by changing the composition of the metal oxide in accordance with the electrical characteristics and reliability required for the transistor, the semiconductor device can have both excellent electrical characteristics and high reliability.

In the case where In—Zn oxide is used for the semiconductor layer of the OS transistor, a metal oxide in which the atomic ratio of indium is higher than or equal to the atomic ratio of zinc may be used. For example, a metal oxide in which the atomic ratio of indium to zinc is In:Zn=1:1, In:Zn=2:1, In:Zn=3:1, In:Zn=4:1, In:Zn=5:1, In:Zn=7:1, or In:Zn=10:1, or in the neighborhood thereof may be used.

In the case where In—Sn oxide is used for the semiconductor layer of the OS transistor, a metal oxide in which the atomic ratio of indium is higher than or equal to the atomic ratio of tin may be used. For example, a metal oxide in which the atomic ratio of indium to tin is In:Sn=1:1, In:Sn=2:1, In:Sn=3:1, In:Sn=4:1, In:Sn=5:1, In:Sn=7:1, or In:Sn=10:1, or in the neighborhood thereof may be used.

In the case where In—Sn—Zn oxide is used for the semiconductor layer of the OS transistor, a metal oxide in which the atomic ratio of indium is higher than the atomic ratio of tin may be used. It is further preferable to use a metal oxide in which the atomic ratio of zinc is higher than the atomic ratio of tin. For example, a metal oxide in which the atomic ratio of indium to tin to zinc is In:Sn:Zn=2:1:3, In:Sn:Zn=3:1:2, In:Sn:Zn=4:2:3, In:Sn:Zn=4:2:4.1, In:Sn:Zn=5:1:3, In:Sn:Zn=5:1:6, In:Sn:Zn=5:1:7, In:Sn:Zn=5:1:8, In:Sn:Zn=6:1:6, In:Sn:Zn=10:1:3, In:Sn:Zn=10:1:6, In:Sn:Zn=10:1:7, In:Sn:Zn=10:1:8, In:Sn:Zn=5:2:5, In:Sn:Zn=10:1:10, In:Sn:Zn=20:1:10, In:Sn:Zn=40:1:10, or in the neighborhood thereof may be used.

In the case where In—Al—Zn oxide is used for the semiconductor layer of the OS transistor, a metal oxide in which the atomic ratio of indium is higher than the atomic ratio of aluminum may be used. It is further preferable to use a metal oxide in which the atomic ratio of zinc is higher than the atomic ratio of aluminum. For example, a metal oxide in which the atomic ratio of indium to aluminum to zinc is In:Al:Zn=2:1:3, In:Al:Zn=3:1:2, In:Al:Zn=4:2:3, In:Al:Zn=4:2:4.1, In:Al:Zn=5:1:3, In:Al:Zn=5:1:6, In:Al:Zn=5:1:7, In:Al:Zn=5:1:8, In:Al:Zn=6:1:6, In:Al:Zn=10:1:3, In:Al:Zn=10:1:6, In:Al:Zn=10:1:7, In:Al:Zn=10:1:8, In:Al:Zn=5:2:5, In:Al:Zn=10:1:10, In:Al:Zn=20:1:10, In:Al:Zn=40:1:10, or in the neighborhood thereof may be used.

In the case where In—Ga—Zn oxide is used for the semiconductor layer of the OS transistor, a metal oxide in which the atomic ratio of indium is higher than the atomic ratio of gallium may be used. It is further preferable to use a metal oxide in which the atomic ratio of zinc is higher than the atomic ratio of gallium. For example, a metal oxide in which the atomic ratio of metal elements is In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, or in the neighborhood thereof may be used in the semiconductor layer.

In the case where In—M—Zn oxide is used for the semiconductor layer of the OS transistor, a metal oxide in which the atomic ratio of indium is higher than the atomic ratio of the element M may be used. It is further preferable to use a metal oxide in which the atomic ratio of zinc is higher than the atomic ratio of the element M. For example, a metal oxide in which the atomic ratio of metal elements is In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, or in the neighborhood thereof may be used in the semiconductor layer.

In the case where In—M—Zn oxide is used for the semiconductor layer, a metal oxide in which the atomic ratio of indium to the element M to zinc is In:M:Zn=1:3:2 [atomic ratio] or in the neighborhood thereof, [atomic ratio] or in the neighborhood thereof, In:M:Zn=1:1:0.5 [atomic ratio] or in the neighborhood thereof, In:M:Zn=1:1:1 [atomic ratio] or in the neighborhood thereof, In:M:Zn=1:1:1.2 [atomic ratio] or in the neighborhood thereof, or In:M:Zn=1:1:2 [atomic ratio] or in the neighborhood thereof may be used. Note that a composition in the neighborhood includes the range of ±30 % of an intended atomic ratio. Gallium is preferably used as the element M.

In the case where a plurality of metal elements are contained as the element M, the sum of the atomic ratios of the metal elements can be the atomic ratio of the element M. In the case of In—Ga—Al—Zn oxide in which gallium and aluminum are contained as the element M, for example, the sum of the atomic ratio of gallium and the atomic ratio of aluminum can be the atomic ratio of the element M. The atomic ratio of indium to the element M to zinc is preferably within the ranges given above.

For analysis of the composition of a metal oxide, for example, energy dispersive X-ray spectroscopy (EDX), X-ray photoelectron spectroscopy (XPS), inductively coupled plasma-mass spectrometry (ICP-MS), or inductively coupled plasma-atomic emission spectrometry (ICP-AES) can be used. Alternatively, such kinds of analysis methods may be performed in combination. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

The metal oxide can be formed by a sputtering method, an ALD method, a metal organic chemical vapor deposition (MOCVD) method, or the like.

Note that in the case where the metal oxide is formed by a sputtering method, the atomic ratio of a target may be different from the atomic ratio of the metal oxide. In particular, the atomic ratio of zinc in the metal oxide is lower than the atomic ratio of zinc in the target in some cases. Specifically, the atomic ratio of zinc contained in the metal oxide may be approximately higher than or equal to 40% and lower than or equal to 90% of the atomic ratio of zinc contained in the target.

When the metal oxide is deposited by a sputtering method, the above atomic ratio is not limited to the atomic ratio of the metal oxide deposited and may be the atomic ratio of a sputtering target used for depositing the metal oxide.

The metal oxide 220b may have a smaller thickness in a region not overlapping with the conductive layer 242 than in a region overlapping with the conductive layer 242. The thin region is formed when part of the top surface of the metal oxide 220b is removed at the time of forming the conductive layer 242a and the conductive layer 242b. When a conductive film to be the conductive layer 242 is deposited, a low-resistance region is sometimes formed on the top surface of the metal oxide 220b in the vicinity of the interface with the conductive film. Removing the low-resistance region positioned between the conductive layer 242a and the conductive layer 242b on the top surface of the metal oxide 220b in this manner can prevent formation of the channel in the region.

The structure of the transistor 750 that can be used in the semiconductor device of one embodiment of the present invention will be described in detail.

The conductive layer 205 is placed to include a region overlapping with the metal oxide 220 and the conductive layer 260. Furthermore, the conductive layer 205 is preferably provided to be embedded in the insulating layer 216.

The conductive layer 205 includes a conductive layer 205a, a conductive layer 205b, and a conductive layer 205c. The conductive layer 205a is provided in contact with the bottom surface and the side wall of the opening provided in the insulating layer 216. The conductive layer 205b is provided to be embedded in a depressed portion formed by the conductive layer 205a. Here, the level of the top surface of the conductive layer 205b is lower than the levels of the top surface of the conductive layer 205a and the top surface of the insulating layer 216. The conductive layer 205c is provided in contact with the top surface of the conductive layer 205b and the side surface of the conductive layer 205a. Here, the top surface of the conductive layer 205c is substantially level with the top surface of the conductive layer 205a and the top surface of the insulating layer 216. In other words, the conductive layer 205b is surrounded by the conductive layer 205a and the conductive layer 205c.

The conductive layer 205a and the conductive layer 205c are preferably formed using a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, the conductive layer 205a and the conductive layer 205c are preferably formed using a conductive material having a function of inhibiting diffusion of oxygen (e.g., at least one of an oxygen atom, an oxygen molecule, and the like).

When the conductive layer 205a and the conductive layer 205c are formed using a conductive material having a function of inhibiting diffusion of hydrogen, impurities such as hydrogen contained in the conductive layer 205b can be inhibited from diffusing into the metal oxide 220 through the insulating layer 224 and the like. When the conductive layer 205a and the conductive layer 205c are formed using a conductive material having a function of inhibiting diffusion of oxygen, the conductivity of the conductive layer 205b can be inhibited from being lowered because of oxidation. As the conductive material having a function of inhibiting diffusion of oxygen, for example, titanium, titanium nitride, tantalum, tantalum nitride, ruthenium, or ruthenium oxide is preferably used. Thus, it is preferable that the conductive layer 205a be a single layer or stacked layers of the above conductive materials. For example, titanium nitride is used for the conductive layer 205a.

The conductive layer 205b is preferably formed using a conductive material containing tungsten, copper, or aluminum as its main component. For example, tungsten is used for the conductive layer 205b.

Here, the conductive layer 260 sometimes functions as a first gate (also referred to as a top gate) electrode. The conductive layer 205 sometimes functions as a second gate (also referred to as a bottom gate) electrode. In that case, by changing a potential applied to the conductive layer 205 independently of a potential applied to the conductive layer 260, threshold voltage (Vth) of the transistor 750 can be controlled. In particular, by applying a negative potential to the conductive layer 205, Vth of the transistor 750 can be increased and the off-state current can be reduced. Thus, a drain current at the time when a potential applied to the conductive layer 260 is 0 V can be lower in the case where a negative potential is applied to the conductive layer 205 than in the case where the negative potential is not applied to the conductive layer 205.

The conductive layer 205 is preferably provided to be larger than the channel formation region in the metal oxide 220. In particular, it is preferable that the conductive layer 205 extend to an outer region beyond an end portion of the metal oxide 220 that intersects with the channel width direction, as shown in FIG. 12C. In other words, the conductive layer 205 and the conductive layer 260 preferably overlap with each other with the insulating layer positioned therebetween, in a region outside the side surface of the metal oxide 220 in the channel width direction.

With the above structure, the channel formation region in the metal oxide 220 can be electrically surrounded by an electric field of the conductive layer 260 having a function of the first gate electrode and an electric field of the conductive layer 205 having a function of the second gate electrode.

The conductive layer 205 may be extended beyond the metal oxide 220 and used as a wiring. However, without limitation to this structure, a structure in which a conductive layer functioning as a wiring is provided below the conductive layer 205 may be employed.

The insulating layer 214 preferably functions as a barrier insulating film that inhibits entry of an impurity such as water or hydrogen to the transistor 750 from the substrate side. Accordingly, it is preferable to use, for the insulating layer 214, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material through which the above impurities are less likely to pass). Alternatively, it is preferable to use an insulating material having a function of inhibiting diffusion of oxygen (e.g., at least one of an oxygen atom, an oxygen molecule, and the like) (an insulating material through which the oxygen is less likely to pass).

For example, aluminum oxide or silicon nitride is preferably used for the insulating layer 214. Accordingly, it is possible to inhibit diffusion of an impurity such as water or hydrogen to the transistor 750 side from the substrate side through the insulating layer 214. Alternatively, it is possible to inhibit diffusion of oxygen contained in the insulating layer 224 and the like to the substrate side through the insulating layer 214.

The permittivity of each of the insulating layer 216, the insulating layer 280, and the insulating layer 281 functioning as an interlayer film is preferably lower than that of the insulating layer 214. When a material with low permittivity is used for an interlayer film, parasitic capacitance generated between wirings can be reduced. For example, for the insulating layer 216, the insulating layer 280, and the insulating layer 281, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, or the like is used as appropriate.

The insulating layer 222 and the insulating layer 224 each have a function of a gate insulating layer.

Here, the insulating layer 224 in contact with the metal oxide 220 preferably releases oxygen by heating. In this specification, oxygen that is released by heating is referred to as excess oxygen in some cases. For example, silicon oxide, silicon oxynitride, or the like is used as appropriate for the insulating layer 224. When an insulating layer containing oxygen is provided in contact with the metal oxide 220, oxygen vacancies in the metal oxide 220 can be reduced, leading to improved reliability of the transistor 750.

Specifically, an oxide material that releases part of oxygen by heating is preferably used for the insulating layer 224. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. Note that the temperature of the film surface in the TDS analysis is preferably within the range of 100° C. to 700° C. or 100° C. to 400° C.

As shown in FIG. 12C, the insulating layer 224 is sometimes thinner in a region overlapping with neither the insulating layer 254 nor the metal oxide 220b than in the other regions. In the insulating layer 224, the region overlapping with neither the insulating layer 254 nor the metal oxide 220b preferably has a thickness with which the above oxygen can be adequately diffused.

Like the insulating layer 214 or the like, the insulating layer 222 preferably functions as a barrier insulating film that inhibits entry of an impurity such as water or hydrogen into the transistor 750 from the substrate side. For example, the insulating layer 222 preferably has lower hydrogen permeability than the insulating layer 224. When the insulating layer 224, the metal oxide 220, the insulating layer 250, and the like are surrounded by the insulating layer 222, the insulating layer 254, and the insulating layer 274, entry of an impurity such as water or hydrogen into the transistor 750 from the outside can be inhibited.

Furthermore, it is preferable that the insulating layer 222 have a function of inhibiting diffusion of oxygen (e.g., at least one of an oxygen atom, an oxygen molecule, and the like) (or be less likely to allow the passage of the above oxygen). For example, the insulating layer 222 preferably has lower oxygen permeability than the insulating layer 224. The insulating layer 222 preferably has a function of inhibiting diffusion of oxygen and impurities, in which case oxygen contained in the metal oxide 220 can be inhibited from diffusing to the substrate side. Moreover, the conductive layer 205 can be inhibited from reacting with oxygen contained in the insulating layer 224 or the metal oxide 220.

As the insulating layer 222, an insulating layer containing an oxide of one or both of aluminum and hafnium, which is an insulating material, is preferably used. As the insulating layer containing an oxide of one or both of aluminum and hafnium, aluminum oxide, hafnium oxide, an oxide containing aluminum and hafnium (hafnium aluminate), or the like is preferably used. In the case where the insulating layer 222 is formed using such a material, the insulating layer 222 functions as a layer inhibiting release of oxygen from the metal oxide 220 and entry of impurities such as hydrogen into the metal oxide 220 from the periphery of the transistor 750.

Alternatively, aluminum oxide, bismuth oxide, germanium oxide, niobium oxide, silicon oxide, titanium oxide, tungsten oxide, yttrium oxide, or zirconium oxide may be added to these insulating layers, for example. Alternatively, these insulating layers may be subjected to nitriding treatment. A stack of the insulating layer and silicon oxide, silicon oxynitride, or silicon nitride may be used. For example, a three-layer structure in which silicon nitride, silicon oxide, and aluminum oxide are stacked in this order can be used for the insulating layer 222.

The insulating layer 222 may be a single layer or a stacked layer formed using an insulating layer containing what is called a high-k material, such as aluminum oxide, hafnium oxide, tantalum oxide, zirconium oxide, lead zirconate titanate (PZT), strontium titanate (SrTiO₃), or (Ba, Sr)TiO₃ (BST). As miniaturization and high integration of transistors progress, a problem such as a leakage current may arise because of a thinner gate insulating layer. When a high-k material is used for the insulating layer functioning as a gate insulating layer, a gate potential at the time of the operation of the transistor can be reduced while the physical thickness is maintained.

Note that the insulating layer 222 and the insulating layer 224 may each have a stacked-layer structure of two or more layers. In that case, the stacked layers are not necessarily formed of the same material and can be formed of different materials. For example, an insulating layer similar to the insulating layer 224 can be provided below the insulating layer 222.

The metal oxide 220 includes the metal oxide 220a, the metal oxide 220b over the metal oxide 220a, and the metal oxide 220c over the metal oxide 220b. When the metal oxide 220 includes the metal oxide 220a under the metal oxide 220b, it is possible to inhibit diffusion of impurities into the metal oxide 220b from the components formed below the metal oxide 220a. Moreover, when the metal oxide 220 includes the metal oxide 220c over the metal oxide 220b, it is possible to inhibit diffusion of impurities into the metal oxide 220b from the components formed above the metal oxide 220c.

Note that the metal oxide 220 preferably has a stacked-layer structure of a plurality of oxide layers that differ in the atomic ratio of metal atoms. For example, in the case where the metal oxide 220 contains at least indium (In) and the element M, the proportion of the number of atoms of the element M contained in the metal oxide 220a to the number of atoms of all elements that constitute the metal oxide 220a is preferably higher than the proportion of the number of atoms of the element M contained in the metal oxide 220b to the number of atoms of all elements that constitute the metal oxide 220b. In addition, the atomic ratio of the element M to In in the metal oxide 220a is preferably higher than the atomic ratio of the element M to In in the metal oxide 220b. Here, a metal oxide that can be used as the metal oxide 220a or the metal oxide 220b can be used as the metal oxide 220c.

The energy of the conduction band minimum of each of the metal oxide 220a and the metal oxide 220c is preferably higher than that of the metal oxide 220b. In other words, the electron affinity of each of the metal oxide 220a and the metal oxide 220c is preferably smaller than that of the metal oxide 220b. In that case, a metal oxide that can be used as the metal oxide 220a is preferably used as the metal oxide 220c. Specifically, the proportion of the number of atoms of the element M contained in the metal oxide 220c to the number of atoms of all elements that constitute the metal oxide 220c is preferably higher than the proportion of the number of atoms of the element M contained in the metal oxide 220b to the number of atoms of all elements that constitute the metal oxide 220b. In addition, the atomic ratio of the element M to In in the metal oxide 220c is preferably higher than the atomic ratio of the element M to In in the metal oxide 220b.

Here, the energy level of the conduction band minimum gently changes at junction portions between the metal oxide 220a, the metal oxide 220b, and the metal oxide 220c. In other words, the energy level of the conduction band minimum at junction portions between the metal oxide 220a, the metal oxide 220b, and the metal oxide 220c continuously changes or is continuously connected. In order to achieve this, the density of defect states in a mixed layer formed at the interface between the metal oxide 220a and the metal oxide 220b and a mixed layer formed at the interface between the metal oxide 220b and the metal oxide 220c is preferably decreased.

Specifically, when the metal oxide 220a and the metal oxide 220b or the metal oxide 220b and the metal oxide 220c contain the same element (as a main component) in addition to oxygen, a mixed layer with a low density of defect states can be formed. For example, in the case where the metal oxide 220b is In—Ga—Zn oxide, as the metal oxide 220a and the metal oxide 220c, In—Ga—Zn oxide, Ga—Zn oxide, gallium oxide, or the like may be used. The metal oxide 220c may have a stacked-layer structure. For example, a stacked-layer structure of In—Ga—Zn oxide and Ga—Zn oxide over the In—Ga—Zn oxide or a stacked-layer structure of In—Ga—Zn oxide and gallium oxide over the In—Ga—Zn oxide can be employed. In other words, the metal oxide 220c may have a stacked-layer structure of In—Ga—Zn oxide and an oxide that does not contain In.

Specifically, as the metal oxide 220a, a metal oxide with In:Ga:Zn=1:3:4 [atomic ratio] or the neighborhood thereof, or 1:1:0.5 [atomic ratio] or the neighborhood thereof may be used. As the metal oxide 220b, a metal oxide with In:Ga:Zn=4:2:3 [atomic ratio] or the neighborhood thereof, 3:1:2 [atomic ratio] or the neighborhood thereof, or 1:1:1 [atomic ratio] or the neighborhood thereof may be used. As the metal oxide 220c, a metal oxide with In:Ga:Zn=1:3:4 [atomic ratio] or the neighborhood thereof, In:Ga:Zn=4:2:3 [atomic ratio] or the neighborhood thereof, Ga:Zn=2:1 [atomic ratio] or the neighborhood thereof, or Ga:Zn=2:5 [atomic ratio] or the neighborhood thereof may be used. Specific examples of a stacked-layer structure of the metal oxide 220c include a stacked-layer structure of a layer with In:Ga:Zn=4:2:3 [atomic ratio] or the neighborhood thereof and a layer with Ga:Zn=2:1 [atomic ratio] or the neighborhood thereof, a stacked-layer structure of a layer with In:Ga:Zn=4:2:3 [atomic ratio] or the neighborhood thereof and a layer with Ga:Zn=2:5 [atomic ratio] or the neighborhood thereof, and a stacked-layer structure of a layer with In:Ga:Zn=4:2:3 [atomic ratio] or the neighborhood thereof and a layer of gallium oxide.

At this time, the metal oxide 220b serves as a main carrier path. When the metal oxide 220a and the metal oxide 220c have the above structure, the density of defect states at the interface between the metal oxide 220a and the metal oxide 220b and the interface between the metal oxide 220b and the metal oxide 220c can be made low. This reduces the influence of interface scattering on carrier conduction, and the transistor 750 can have a high on-state current and high frequency characteristics. Note that in the case where the metal oxide 220c has a stacked-layer structure, not only the effect of reducing the density of defect states at the interface between the metal oxide 220b and the metal oxide 220c, but also the effect of inhibiting diffusion of the constituent element of the metal oxide 220c to the insulating layer 250 side can be expected. Specifically, the metal oxide 220c has a stacked-layer structure in which the upper layer is an oxide that does not contain In, whereby the amount of In that would diffuse to the insulating layer 250 side can be reduced. Since the insulating layer 250 functions as a gate insulating layer, the transistor would show poor characteristics when In diffuses into the insulating layer 250. Thus, the metal oxide 220c having a stacked-layer structure allows a highly reliable semiconductor device to be provided.

The conductive layer 242 (the conductive layer 242a and the conductive layer 242b) functioning as the source electrode and the drain electrode is provided over the metal oxide 220b. For the conductive layer 242, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing any of the above metal elements as its component; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. In addition, tantalum nitride, titanium nitride, a nitride including titanium and aluminum, a nitride including tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen.

When the conductive layer 242 is provided in contact with the metal oxide 220, the oxygen concentration of the metal oxide 220 in the vicinity of the conductive layer 242 sometimes decreases. In addition, a metal compound layer that contains the metal contained in the conductive layer 242 and the component of the metal oxide 220 is sometimes formed in the metal oxide 220 in the vicinity of the conductive layer 242. In such a case, the carrier concentration of the region in the metal oxide 220 in the vicinity of the conductive layer 242 increases, and the region becomes a low-resistance region.

Here, the region between the conductive layer 242a and the conductive layer 242b is formed to overlap with the opening of the insulating layer 280. Accordingly, the conductive layer 260 can be placed in a self-aligned manner between the conductive layer 242a and the conductive layer 242b.

The insulating layer 250 functions as a gate insulating layer. The insulating layer 250 is preferably placed in contact with the top surface of the metal oxide 220c. For the insulating layer 250, any of silicon oxide, silicon oxynitride, silicon nitride oxide, silicon nitride, silicon oxide to which fluorine is added, silicon oxide to which carbon is added, silicon oxide to which carbon and nitrogen are added, and porous silicon oxide can be used. In particular, silicon oxide and silicon oxynitride are preferable because they are thermally stable.

As in the insulating layer 224, the concentration of an impurity such as water or hydrogen is preferably reduced in the insulating layer 250. The thickness of the insulating layer 250 is preferably greater than or equal to 1 nm and less than or equal to 20 nm.

A metal oxide may be provided between the insulating layer 250 and the conductive layer 260. The metal oxide preferably inhibits oxygen diffusion from the insulating layer 250 into the conductive layer 260. Accordingly, oxidation of the conductive layer 260 due to oxygen in the insulating layer 250 can be inhibited.

The metal oxide has a function of part of the gate insulating layer in some cases. Therefore, when silicon oxide, silicon oxynitride, or the like is used for the insulating layer 250, a metal oxide that is a high-k material with a high dielectric constant is preferably used as the metal oxide. When the gate insulating layer has a stacked-layer structure of the insulating layer 250 and the metal oxide, the stacked-layer structure can be thermally stable and have a high dielectric constant. Accordingly, a gate potential applied during the operation of the transistor can be reduced while the physical thickness of the gate insulating layer is maintained. In addition, the equivalent oxide thickness (EOT) of the insulating layer functioning as the gate insulating layer can be reduced.

Specifically, a metal oxide containing one kind or two or more kinds selected from hafnium, aluminum, gallium, yttrium, zirconium, tungsten, titanium, tantalum, nickel, germanium, magnesium, and the like can be used. It is particularly preferable to use an insulator containing an oxide of one or both of aluminum and hafnium, such as aluminum oxide, hafnium oxide, or an oxide containing aluminum and hafnium (hafnium aluminate).

Although FIG. 12A to FIG. 12C show the conductive layer 260 having a two-layer structure, the conductive layer 260 can have a single-layer structure or a stacked-layer structure of three or more layers.

The conductive layer 260a is preferably formed using the aforementioned conductive layer having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, the conductive layer 260a is preferably formed using a conductive material having a function of inhibiting diffusion of oxygen (e.g., at least one of an oxygen atom, an oxygen molecule, and the like).

When the conductive layer 260a has a function of inhibiting diffusion of oxygen, the conductivity of the conductive layer 260b can be inhibited from being lowered because of oxidation due to oxygen contained in the insulating layer 250. As a conductive material having a function of inhibiting diffusion of oxygen, for example, tantalum, tantalum nitride, ruthenium, ruthenium oxide, or the like is preferably used.

The conductive layer 260b is preferably formed using a conductive material containing tungsten, copper, or aluminum as its main component. The conductive layer 260 also functions as a wiring and thus is preferably formed using a conductive layer having high conductivity. For example, a conductive material containing tungsten, copper, or aluminum as its main component can be used. The conductive layer 260b may have a stacked-layer structure, for example, a stacked-layer structure of any of the above conductive materials and titanium or titanium nitride.

As shown in FIG. 12A and FIG. 12C, the side surface of the metal oxide 220 is placed to be covered with the conductive layer 260 in a region where the metal oxide 220b does not overlap with the conductive layer 242, that is, the channel formation region of the metal oxide 220. Accordingly, the electric field of the conductive layer 260 functioning as the first gate electrode is likely to act on the side surface of the metal oxide 220. Hence, the transistor 750 can have a higher on-state current and higher frequency characteristics.

Like the insulating layer 214 or the like, the insulating layer 254 preferably functions as a barrier insulating film that inhibits entry of an impurity such as water or hydrogen into the transistor 750 from the insulating layer 280 side. For example, the insulating layer 254 preferably has lower hydrogen permeability than the insulating layer 224. Furthermore, as shown in FIG. 12B and FIG. 12C, the insulating layer 254 is preferably in contact with the side surface of the metal oxide 220c, the top surface and the side surface of the conductive layer 242a, the top surface and the side surface of the conductive layer 242b, the side surfaces of the metal oxide 220a and the metal oxide 220b, and the top surface of the insulating layer 224. Such a structure can inhibit entry of hydrogen contained in the insulating layer 280 into the metal oxide 220 through the top surfaces or the side surfaces of the conductive layer 242a, the conductive layer 242b, the metal oxide 220a, the metal oxide 220b, and the insulating layer 224.

Furthermore, it is preferable that the insulating layer 254 have a function of inhibiting diffusion of oxygen (e.g., at least one of an oxygen atom, an oxygen molecule, and the like) (or be less likely to allow the passage of the above oxygen). For example, the insulating layer 254 preferably has lower oxygen permeability than the insulating layer 280 or the insulating layer 224.

The insulating layer 254 is preferably deposited by a sputtering method. When the insulating layer 254 is deposited by a sputtering method in an oxygen-containing atmosphere, oxygen can be added to the vicinity of a region of the insulating layer 224 which is in contact with the insulating layer 254. Thus, oxygen can be supplied from the region into the metal oxide 220 through the insulating layer 224. Here, with the insulating layer 254 having a function of inhibiting upward oxygen diffusion, oxygen can be prevented from diffusing from the metal oxide 220 into the insulating layer 280. Moreover, with the insulating layer 222 having a function of inhibiting downward oxygen diffusion, oxygen can be prevented from diffusing from the metal oxide 220 to the substrate side. In the above manner, oxygen is supplied to the channel formation region of the metal oxide 220. Accordingly, oxygen vacancies in the metal oxide 220 can be reduced, so that the transistor can be inhibited from becoming normally on.

As the insulating layer 254, an insulating layer containing an oxide of one or both of aluminum and hafnium is deposited, for example. Note that as the insulating layer containing an oxide of one or both of aluminum and hafnium, aluminum oxide, hafnium oxide, an oxide containing aluminum and hafnium (hafnium aluminate), or the like is preferably used.

The insulating layer 280 is provided over the insulating layer 224, the metal oxide 220, and the conductive layer 242 with the insulating layer 254 therebetween. The insulating layer 280 preferably contains, for example, silicon oxide, silicon oxynitride, silicon nitride oxide, silicon oxide to which fluorine is added, silicon oxide to which carbon is added, silicon oxide to which carbon and nitrogen are added, or porous silicon oxide. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed.

The concentration of an impurity such as water or hydrogen in the insulating layer 280 is preferably reduced. In addition, the top surface of the insulating layer 280 may be planarized.

Like the insulating layer 214 or the like, the insulating layer 274 preferably functions as a barrier insulating film that inhibits entry of an impurity such as water or hydrogen into the insulating layer 280 from above. As the insulating layer 274, the insulating layer that can be used as the insulating layer 214, the insulating layer 254, or the like is used, for example.

The insulating layer 281 functioning as an interlayer film is preferably provided over the insulating layer 274. As in the insulating layer 224 or the like, the concentration of an impurity such as water or hydrogen is preferably reduced in the insulating layer 281.

The conductive layer 245a and the conductive layer 245b are placed in an opening formed in the insulating layer 281, the insulating layer 274, the insulating layer 280, and the insulating layer 254. The conductive layer 245a and the conductive layer 245b are provided to face each other with the conductive layer 260 therebetween. Note that the top surfaces of the conductive layer 245a and the conductive layer 245b may be on the same plane as the top surface of the insulating layer 281.

Note that the insulating layer 241a is provided in contact with the inner wall of the opening in the insulating layer 281, the insulating layer 274, the insulating layer 280, and the insulating layer 254, and a first conductive layer of the conductive layer 245a is formed in contact with the side surface of the insulating layer 241a. The conductive layer 242a is positioned on at least part of the bottom portion of the opening, and the conductive layer 245a is in contact with the conductive layer 242a. Similarly, the insulating layer 241b is provided in contact with the inner wall of the opening in the insulating layer 281, the insulating layer 274, the insulating layer 280, and the insulating layer 254, and a first conductive layer of the conductive layer 245b is formed in contact with the side surface of the insulating layer 241b. The conductive layer 242b is positioned on at least part of the bottom portion of the opening, and the conductive layer 245b is in contact with the conductive layer 242b.

The conductive layer 245a and the conductive layer 245b are preferably formed using a conductive material containing tungsten, copper, or aluminum as its main component. The conductive layer 245a and the conductive layer 245b may each have a stacked-layer structure.

In the case where the conductive layer 245 has a stacked-layer structure, the aforementioned conductive layer having a function of inhibiting diffusion of an impurity such as water or hydrogen is preferably used as the conductive layer in contact with the metal oxide 220a, the metal oxide 220b, the conductive layer 242, the insulating layer 254, the insulating layer 280, the insulating layer 274, and the insulating layer 281. For example, tantalum, tantalum nitride, titanium, titanium nitride, ruthenium, ruthenium oxide, or the like is preferably used. The conductive material having a function of inhibiting diffusion of impurities such as water or hydrogen can be used as a single layer or stacked layers. The use of the conductive material can inhibit oxygen added to the insulating layer 280 from being absorbed by the conductive layer 245a and the conductive layer 245b. Moreover, an impurity such as water or hydrogen can be inhibited from entering the metal oxide 220 through the conductive layer 245a and the conductive layer 245b from a layer above the insulating layer 281.

As the insulating layer 241a and the insulating layer 241b, the insulating layer that can be used as the insulating layer 254 or the like is used, for example. Since the insulating layer 241a and the insulating layer 241b are provided in contact with the insulating layer 254, an impurity such as water or hydrogen in the insulating layer 280 or the like can be inhibited from entering the metal oxide 220 through the conductive layer 245a and the conductive layer 245b. Furthermore, oxygen contained in the insulating layer 280 can be inhibited from being absorbed by the conductive layer 245a and the conductive layer 245b.

Although not shown, a conductive layer functioning as a wiring may be placed in contact with the top surface of the conductive layer 245a and the top surface of the conductive layer 245b. For the conductive layer functioning as a wiring, a conductive material containing tungsten, copper, or aluminum as its main component is preferably used. Furthermore, the conductive layer may have a stacked-layer structure and may be a stack of titanium or titanium nitride and the above conductive material, for example. The conductive layer may be formed to be embedded in an opening provided in an insulating layer.

### <Structure Example 2 of Transistor>

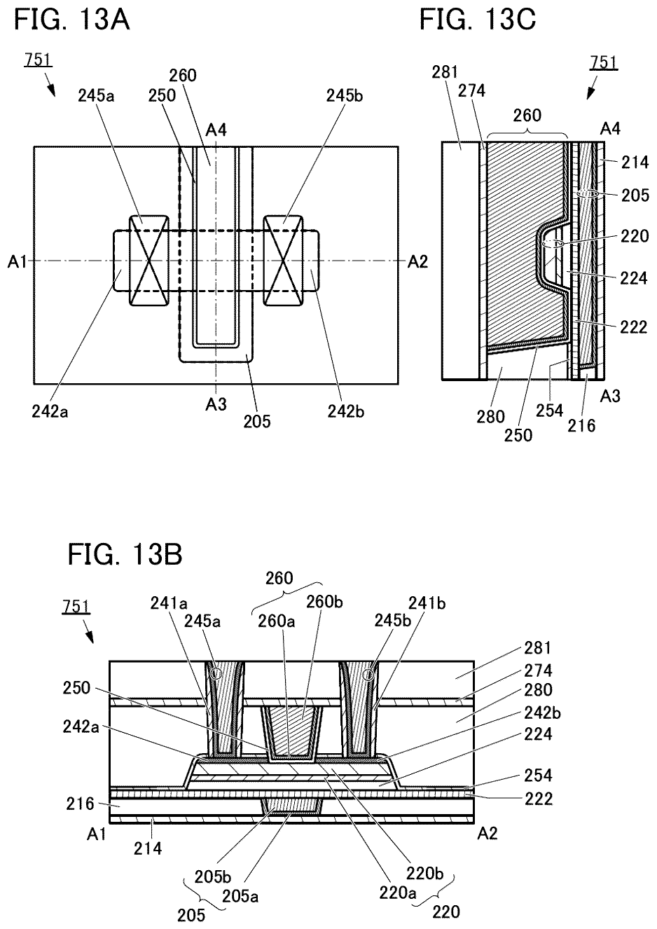

FIG. 13 shows a modification example of the transistor 750 shown in FIG. 12. FIG. 13A, FIG. 13B, and FIG. 13C are a plan view and cross-sectional views of a transistor 751, which is a modification example of the transistor 750. The transistor 751 is a modification example of the transistor 750; thus, different points of the transistor 751 from the transistor 750 are mainly described.

The transistor 751 has a structure in which the metal oxide 220c and the conductive layer 205c are removed from the structure of the transistor 750. A reduction in the number of components of a transistor can reduce the production cost. Furthermore, the manufacturing process is shortened when the number of components of the transistor is reduced, leading to an improvement of the manufacturing yield.

The transistor 751 includes a region where the insulating layer 254 and the insulating layer 222 are in contact with each other outside the metal oxide 220, and has a structure in which the side surface of the insulating layer 224 is covered with the insulating layer 254. When the side surface of the insulating layer 224 is covered with the insulating layer 254, oxygen can be prevented from diffusing to the outside through the insulating layer 224, and excess oxygen supply from the insulating layer 224 side to the metal oxide 220 can be prevented as well.

Note that an insulating layer may be provided between the insulating layer 250 and the insulating layer 280, the insulating layer 254, the conductive layer 242, and the metal oxide 220b. Aluminum oxide, hafnium oxide, or the like is preferably used for the insulating layer. Providing the insulating layer can inhibit release of oxygen from the metal oxide 220 to the insulating layer 250 side, supply of excess oxygen from the insulating layer 250 side to the metal oxide 220, oxidation of the conductive layer 242, and the like.

### <Structure Example 3 of Transistor>

Next, a transistor 752 having a structure different from those of the transistor 750 and the transistor 751 will be described. Like the transistor 750 and the transistor 751, the transistor 752 can also be used in the semiconductor device of one embodiment of the present invention.

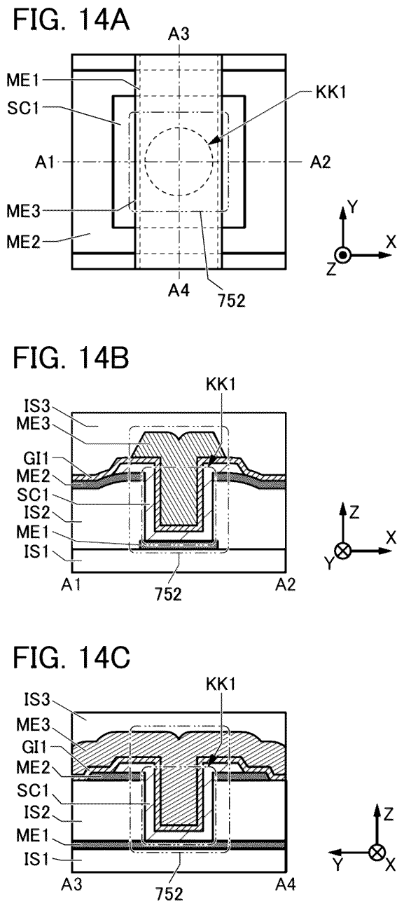

FIG. 14A is the plan view of the transistor 752. FIG. 14B is a cross-sectional view taken along dashed-dotted line A1-A2 in FIG. 14A. FIG. 14C is a cross-sectional view taken along dashed-dotted line A3-A4 in FIG. 14A.

In FIG. 14A to FIG. 14C, the direction along the dashed-dotted line A1-A2 is the X direction and the direction along the dashed-dotted line A3-A4 is the Y direction. Furthermore, the direction perpendicular to both the X direction and the Y direction is the Z direction.

The transistor 752 shown in FIG. 14A to FIG. 14C includes an insulating layer IS1 to an insulating layer IS3, an insulating layer GII, a conductive layer MEI to a conductive layer ME3, and a semiconductor SC1.

The insulating layer IS1 functions as a base film above which a source, a drain, and a channel formation region of the transistor 752 are provided, for example. For the insulating layer IS1, silicon oxide, silicon oxynitride, silicon nitride oxide, or silicon nitride can be used, for example. For the insulating layer IS1, for example, silicon oxide to which fluorine is added, silicon oxide to which carbon is added, silicon oxide to which carbon and nitrogen are added, or porous silicon oxide can be used. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed. Alternatively, for example, a resin can be used for the insulating layer IS1. A material combined with any of the above insulating materials as appropriate may be used for the insulating layer IS1.

The conductive layer ME1 is a conductive layer (sometimes referred to as a terminal, a wiring, or the like) functioning as one of a source and a drain in the transistor 752. The conductive layer ME2 is a conductive layer (sometimes referred to as a terminal, a wiring, or the like) functioning as the other of the source and the drain in the transistor 752.

Note that in FIG. 14A to FIG. 14C, the conductive layer ME1 is provided to extend in the Y direction as a wiring, for example. The conductive layer ME2 is provided to extend in the X direction as a wiring, for example.

For the conductive layer ME1, the conductive layer ME2, and the conductive layer ME3, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing two or more selected from the above metal elements as its components; or an alloy containing a combination of two or more selected from the above metal elements. For example, for the conductive layer ME1, the conductive layer ME2, and the conductive layer ME3, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, or an oxide containing lanthanum and nickel. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. For the conductive layers, a semiconductor having high electrical conductivity, typified by polycrystalline silicon containing an impurity element (e.g., phosphorus or arsenic), or silicide (e.g., nickel silicide) may be used.

Alternatively, a conductive oxide may be used for the conductive layer ME1, the conductive layer ME2, and the conductive layer ME3. Examples of the conductive oxide include indium oxide, zinc oxide, In—Sn oxide (ITO), In—Zn oxide (also referred to as IZO (registered trademark)), In—W oxide, In—W—Zn oxide, In—Ti oxide, In—Ti—Sn oxide, In—Sn—Si oxide (also referred to as ITO containing silicon or ITSO), zinc oxide to which gallium is added, and In—Ga—Zn oxide. A conductive oxide containing indium is particularly preferable because of its high conductivity.

A stack of a plurality of conductive films formed using any of the above materials may be used. For example, a stacked-layer structure combining a material containing the above-described metal element and a conductive material containing oxygen may be employed. Specific examples of the stacked-layer structure of the conductive film include a stacked-layer structure of indium oxide and a metal film containing ruthenium. In addition, a stacked-layer structure combining a material containing the above-described metal element and a conductive material containing nitrogen may be employed. Furthermore, a stacked-layer structure combining a material containing the above-described metal element, a conductive material containing oxygen, and a conductive material containing nitrogen may be employed.

The insulating layer IS2 functions as an interlayer film that separates the source and the drain of the transistor 752, for example. Any of the materials that can be used for the insulating layer IS1 can be used as the insulating layer IS2, for example. In the case where the semiconductor SC1 is a metal oxide functioning as an oxide semiconductor, silicon oxide, silicon oxynitride, or porous silicon oxide is preferably used. These materials are capable of easily forming a region containing oxygen that is released by heating, so that the released oxygen can be supplied to the metal oxide. This reduces the carrier concentration of the metal oxide at the interface of the semiconductor SC1 in contact with the insulating layer IS2 and in the vicinity of the interface, whereby the interface of the semiconductor SC1 and the vicinity of the interface become i-type or substantially i-type. Accordingly, the interface of the semiconductor SC1 and the vicinity of the interface can function as the channel formation region of the transistor 752.

For example, the semiconductor SC1 can be a metal oxide functioning as an oxide semiconductor. In this case, the transistor 752 is an OS transistor. The metal oxide preferably contains at least indium or zinc, for example. In particular, indium and zinc are preferably contained. In addition to them, the element M is preferably contained. As the element M, one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, magnesium, cobalt, and antimony can be used. In particular, the element M is preferably one or more of aluminum, gallium, yttrium, and tin. The element M further preferably contains one or both of gallium and tin.

More specific examples of the metal oxide include indium oxide, gallium oxide, zinc oxide, indium zinc oxide (In—Zn oxide, also referred to as IZO (registered trademark)), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide, also referred to as ITZO (registered trademark)), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), and indium gallium aluminum zinc oxide (In—Ga—Al—Zn oxide, also referred to as IGAZO, IGZAO, or IAGZO). Other examples include indium tin oxide containing silicon, gallium tin oxide (Ga—Sn oxide), and aluminum tin oxide (Al—Sn oxide). Note that a material that does not contain Zn, typically indium oxide or the like, is preferred because of having excellent compatibility with a Si process. By contrast, a material that contains Zn is preferred in that crystallinity can be increased.

In the case where the semiconductor SC1 is a metal oxide functioning as an oxide semiconductor, it is preferably formed by an ALD method. As shown in FIG. 14B and FIG. 14C, when the semiconductor SC1 is formed in a region having a step, an ALD method enables formation with favorable coverage.

In the case where a metal oxide functioning as an oxide semiconductor is used as the semiconductor SC1, microwave treatment is preferably performed in an oxygen-containing atmosphere during or after the deposition of the metal oxide to reduce the impurity concentration in the metal oxide. Note that specific examples of impurities include hydrogen and carbon. The microwave treatment can increase the crystallinity of the metal oxide in some cases. Here, the microwave treatment refers to, for example, treatment using an apparatus including a power source that generates high-density plasma with the use of a microwave.

Note that it is preferable to use a metal oxide layer having crystallinity as the semiconductor SC1. For example, a metal oxide layer having a CAAC (c-axis-aligned crystalline) structure, a polycrystalline structure, a nanocrystalline (nc) structure, or the like can be used. With use of the metal oxide layer having crystallinity as the semiconductor SC1, the density of defect states in the semiconductor SC1 can be reduced, which enables the semiconductor device to have high reliability.

For example, an In—Ga—Zn oxide is preferably used for the semiconductor SC1. The In—Ga—Zn oxide is further preferably a metal oxide with a composition of In:Ga:Zn=1:1:1 [atomic ratio] or in the neighborhood thereof, a composition of 4:2:3 [atomic ratio] or in the neighborhood thereof, or a composition of 3:1:2 [atomic ratio] or in the neighborhood thereof, in particular. As another example, an In—Zn oxide is preferably used for the semiconductor film SCIA. The In—Zn oxide is further preferably a metal oxide with a composition of In:Zn=4:1 [atomic ratio] or in the neighborhood thereof, in particular.

The semiconductor SC1 preferably has a stacked-layer structure of a plurality of oxide layers that differ in the atomic ratio of metal atoms, for example. For example, the first metal oxide and the second metal oxide formed over the first metal oxide are assumed as the metal oxide. In the case where each metal oxide contains at least indium (In) and the element M, the proportion of the number of atoms of the element M contained in the first metal oxide to the number of atoms of all elements that constitute the first metal oxide is preferably higher than the proportion of the number of atoms of the element M contained in the second metal oxide to the number of atoms of all elements that constitute the second metal oxide. In addition, the atomic ratio of the element M to In in the first metal oxide is preferably higher than the atomic ratio of the element M to In in the second metal oxide.

Specifically, as the first metal oxide, a metal oxide with a composition of In:Ga:Zn=1:3:4 [atomic ratio] or in the neighborhood thereof, a composition of 1:3:2 [atomic ratio] or in the neighborhood thereof, or a composition of 1:1:0.5 [atomic ratio] or in the neighborhood thereof can be used. As the second metal oxide, a metal oxide with a composition of In:Ga:Zn=1:1:1 [atomic ratio] or in the neighborhood thereof, a composition of 4:2:3 [atomic ratio] or in the neighborhood thereof, or a composition of 3:1:2 [atomic ratio] or in the neighborhood thereof is used. Note that a composition in the neighborhood includes the range of ±30 % of an intended atomic ratio.

At this time, the second metal oxide serves as a main carrier path. When the first metal oxide has the above structure, the density of defect states at the interface between the first metal oxide and the second metal oxide can be made low. This reduces the influence of interface scattering on carrier conduction, and the transistor can have a high on-state current and high frequency characteristics.

In a region of the insulating layer IS2 where the transistor 752 is provided, an opening KK1 whose side surface is substantially perpendicular to the X-Y plane (the taper angle is greater than or equal to 70° and less than or equal to 110°) is formed. The semiconductor SC1 including the channel formation region of the transistor 752 is provided to be in contact with the conductive layer ME1 and the conductive layer ME2 through the opening KK1.

In the transistor 752, the insulating layer GI1 is provided over the semiconductor SC1. Specifically, the insulating layer GI1 is positioned above and overlaps with the channel formation region included in the semiconductor SC1 in the plan view. The insulating layer GI1 functions as a gate insulating film of the transistor 752.

The insulating layer GI1 is preferably a single layer or a stacked layer formed using an insulating layer containing what is called a high-k material, such as aluminum oxide, hafnium oxide, tantalum oxide, zirconium oxide, lead zirconate titanate (PZT), strontium titanate (SrTiO₃), or (Ba, Sr)TiO₃ (BST). Alternatively, the insulating layer GII may be formed using, as an insulating layer having a high dielectric constant, an oxide containing aluminum and hafnium, an oxynitride containing aluminum and hafnium, an oxide containing silicon and hafnium (also referred to as hafnium silicate or HfₓSiO_{y} (x and y are each a given number), an oxynitride containing silicon and hafnium, or a nitride containing silicon and hafnium. Alternatively, the insulating layer GI1 may be formed using a material that can be used for the insulating layer IS1. For example, the insulating layer GI1 may be formed using silicon oxide, silicon oxynitride, silicon nitride oxide, or silicon nitride.

In the transistor 752, the conductive layer ME3 is provided over the insulating layer GI1 to fill the opening KK1. The conductive layer ME3 is a conductive layer (sometimes referred to as a terminal, a wiring, or the like) functioning as a gate in the transistor 752.

Note that in FIG. 14A to FIG. 14C, the conductive layer ME3 is provided to extend in the Y direction as a wiring, for example.

The insulating layer IS3 is a film functioning as an interlayer film, for example. Thus, the insulating layer IS3 preferably contains an insulating material with a low dielectric constant. The use of an insulating material with a low dielectric constant for the interlayer film can reduce the parasitic capacitance between wirings.

Any of the materials that can be used for the insulating layer IS1 can be used as the insulating layer IS3, for example.

As described above, in the transistor 752 shown in FIG. 14A to FIG. 14C, the conductive layer ME1 functioning as one of the source and the drain is positioned below the insulating layer IS2 functioning as an interlayer film, and the conductive layer ME2 functioning as the other of the source and the drain is positioned above the insulating layer IS2. Thus, the channel formation region of the transistor 752 is provided along the opening of the insulating layer IS2.

In the transistor 752, the source and the drain are positioned at different levels, so that a current flows in the semiconductor layer in the height direction. In other words, the channel length direction can be regarded as having a component of the height direction (the vertical direction); accordingly, the transistor 752 can also be referred to as a VFET (Vertical Field Effect Transistor), a vertical transistor, a vertical-channel transistor, a vertical-channel-type transistor, and the like.

As shown in FIG. 14A to FIG. 14C, when the channel formation region of the transistor is provided along the side surface of the opening of the insulating layer functioning as an interlayer film, the area occupied by the transistor can be smaller than that in the case where the channel formation region of the transistor is provided along the X-Y plane. Thus, when a circuit is formed using one or both of the transistor 752, the area of the circuit can be small. As a result, a semiconductor device including the circuit or a semiconductor device can be downsized.

### <Constituent Materials of Semiconductor Device Including Transistor>

Next, constituent materials that can be used for the semiconductor device including the transistor will be described.

### [Substrate]

In the case where the semiconductor device including the transistor is provided over a substrate, there is no particular limitation on a material used for the substrate. The material can be determined by the purpose in consideration of whether it has a light-transmitting property, heat resistance high enough to withstand heat treatment, or the like. For example, an insulating substrate, a semiconductor substrate, or a conductive substrate may be used. Examples of the insulating substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon, germanium, or the like and a compound semiconductor substrate including silicon carbide, silicon germanium, gallium arsenide, indium phosphide, zinc oxide, gallium oxide, or gallium nitride. Another example is a semiconductor substrate having an insulator region in the semiconductor substrate described above, e.g., an SOI (Silicon On Insulator) substrate. Examples of the conductive substrate include a graphite substrate, a metal substrate, an alloy substrate, and a conductive resin substrate. Other examples include a substrate containing a metal nitride and a substrate containing a metal oxide. Other examples include an insulating substrate provided with a conductive layer or a semiconductor, a semiconductor substrate provided with a conductive layer or an insulating layer, and a conductive substrate provided with a semiconductor or an insulating layer. Alternatively, these substrates provided with elements may be used. Examples of the elements provided over the substrates include a capacitor element, a resistor element, a switching element, a light-emitting element, and a storage element.

### [Insulating Layer]

An insulating oxide, an insulating nitride, an insulating oxynitride, an insulating nitride oxide, an insulating metal oxide, an insulating metal oxynitride, an insulating metal nitride oxide, or the like can be used for the insulating layer. For example, a single layer or a stacked layer of an insulating material selected from aluminum nitride, aluminum oxide, aluminum nitride oxide, aluminum oxynitride, magnesium oxide, silicon nitride, silicon oxide, silicon nitride oxide, silicon oxynitride, gallium oxide, germanium oxide, yttrium oxide, zirconium oxide, lanthanum oxide, neodymium oxide, hafnium oxide, tantalum oxide, aluminum silicate, and the like is used as the insulating layer. Two or more selected from an oxide material, a nitride material, an oxynitride material, and a nitride oxide material may be used.

Note that in this specification and the like, a nitride oxide refers to a material that contains more nitrogen than oxygen. An oxynitride refers to a material that contains more oxygen than nitrogen. Note that the content of each element can be measured by Rutherford backscattering spectrometry (RBS), for example.

As miniaturization and high integration of transistors progress, a problem such as leakage current may arise because of a thinner gate insulating layer. When a high-k material (a material with a high relative dielectric constant) is used for an insulating layer functioning as the gate insulating layer, a gate potential during operation of the transistor can be reduced while the physical thickness is maintained. A substance with a high dielectric constant, such as lead zirconate titanate (PZT), strontium titanate (SrTiO₃), or (Ba, Sr)TiO₃ (BST), can be used for the insulating layer in some cases. By contrast, when a material with a low relative dielectric constant is used for the insulating layer functioning as an interlayer film, parasitic capacitance generated between wirings can be reduced. Thus, selecting a material depending on the function needed for the insulating layer is particularly important.

Examples of the insulating layer with a high dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulating layer with a low dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

There is no particular limitation on the formation method of the insulating material, and a variety of formation methods such as an evaporation method, an atomic layer deposition (ALD) method, a chemical vapor deposition (CVD) method, a sputtering method, and a spin coating method can be employed.

When a transistor including an oxide semiconductor is surrounded by insulating layers having a function of inhibiting passage of oxygen and impurities such as hydrogen (e.g., the insulating layer 214, the insulating layer 222, the insulating layer 254, and the insulating layer 274), the transistor can have stable electrical characteristics. As the insulating layer having a function of inhibiting passage of oxygen and impurities such as hydrogen, a single layer or stacked layers of an insulating layer containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum are used. Specifically, as the insulating layer having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, aluminum titanium nitride, titanium nitride, silicon nitride oxide, or silicon nitride can be used.

The insulating layer functioning as the gate insulating layer is preferably an insulating layer including a region containing oxygen to be released by heating. For example, when a structure is employed in which silicon oxide or silicon oxynitride including a region containing oxygen to be released by heating is in contact with the metal oxide 220, oxygen vacancies included in the metal oxide 220 can be compensated for.

### [Conductive Layer]

As a conductive layer, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are conductive materials that are less likely to be oxidized or materials that maintain their conductivity even after absorbing oxygen. A semiconductor having high electrical conductivity, typified by polycrystalline silicon containing an impurity element such as phosphorus, or silicide such as nickel silicide may be used. There is no particular limitation on the formation method of the conductive material, and a variety of formation methods such as an evaporation method, an ALD method, a CVD method, a sputtering method, and a spin coating method can be employed.

A Cu-X alloy (X is Mn, Ni, Cr, Fe, Co, Mo, Ta, or Ti) may be used as the conductive layer. A conductive layer formed using a Cu-X alloy can be processed with a wet etching process, resulting in lower manufacturing cost. Alternatively, an aluminum alloy containing one or more elements selected from titanium, tantalum, tungsten, molybdenum, chromium, neodymium, and scandium may be used as the conductive layer.

A stack of a plurality of conductive layers formed of the above-described materials may be used. For example, a stacked-layer structure combining a material containing the above-described metal element and a conductive material containing oxygen may be employed. In addition, a stacked-layer structure combining a material containing the above-described metal element and a conductive material containing nitrogen may be employed. Furthermore, a stacked-layer structure combining a material containing the above-described metal element, a conductive material containing oxygen, and a conductive material containing nitrogen may be employed.

In the case where a metal oxide is used for the channel formation region of the transistor, the conductive layer functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductive layer functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. Indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulating layer or the like can be captured in some cases.

### [Semiconductor Layer]

For the semiconductor layer, a single crystal semiconductor, a polycrystalline semiconductor, a microcrystalline semiconductor, an amorphous semiconductor, or the like can be used alone or in combination. As a semiconductor material, silicon, germanium, or the like can be used, for example. Alternatively, a compound semiconductor such as silicon germanium, silicon carbide, gallium arsenide, or a nitride semiconductor may be used. As the compound semiconductor, an organic substance having semiconductor characteristics or a metal oxide having semiconductor characteristics (also referred to as an oxide semiconductor) can be used. These semiconductor materials may include an impurity as a dopant.

For the semiconductor layer, single crystal silicon, polycrystalline silicon, microcrystalline silicon, and amorphous silicon may be used, for example. As the poly crystalline silicon, for example, low-temperature polysilicon (LTPS) may be used.

An oxide semiconductor has a band gap of 2 eV or more; thus, a transistor using an oxide semiconductor, which is a kind of metal oxide, for a semiconductor layer where a channel is formed (an OS transistor) has an extremely low off-state current. Thus, the power consumption of a semiconductor device including an OS transistor can be reduced. The OS transistor operates stably even in a high-temperature environment and has small change in characteristics. For example, the off-state current hardly increases even in a high-temperature environment. Specifically, the off-state current hardly increases even at an environmental temperature higher than or equal to room temperature and lower than or equal to 200° C. Furthermore, the on-state current of the OS transistor is unlikely to decrease even in a high-temperature environment. Therefore, the semiconductor device including the OS transistor can operate stably and have high reliability even in a high-temperature environment.

The metal oxide can be formed by a sputtering method, an ALD method, a metal organic chemical vapor deposition (MOCVD) method, or the like.

Note that in the case where the metal oxide is formed by a sputtering method, the atomic ratio of a target may be different from the atomic ratio of the metal oxide. In particular, the atomic ratio of zinc in the metal oxide is lower than the atomic ratio of zinc in the target in some cases. Specifically, the atomic ratio of zinc contained in the metal oxide may be approximately higher than or equal to 40% and lower than or equal to 90% of the atomic ratio of zinc contained in the target.

When the metal oxide is deposited by a sputtering method, the above atomic ratio is not limited to the atomic ratio of the metal oxide deposited and may be the atomic ratio of a sputtering target used for depositing the metal oxide.

The structure described in this embodiment can be used in an appropriate combination with the structures described in the other embodiments.

### EMBODIMENT 3

In this embodiment, stacked-layer structure examples of the semiconductor device of one embodiment of the present invention will be described.

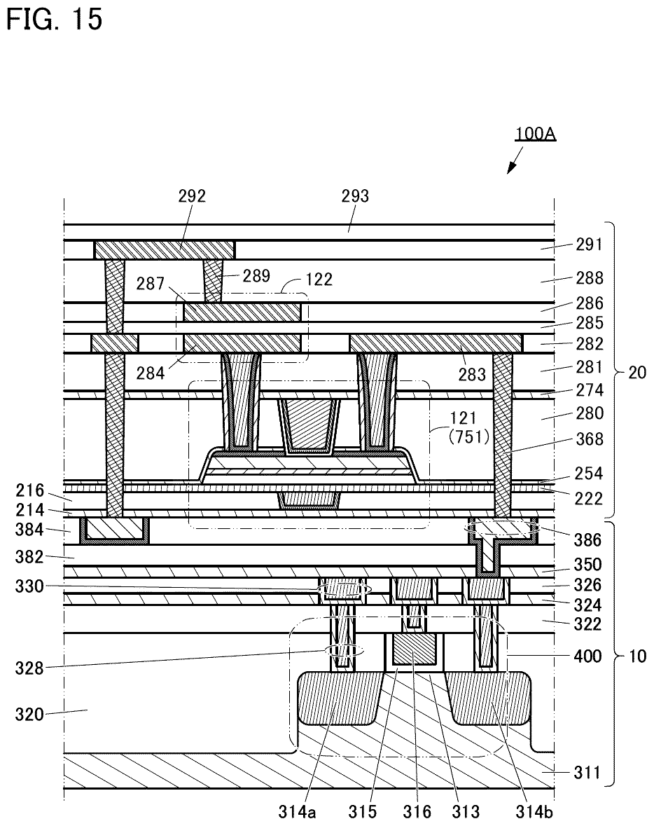

FIG. 15 shows a stacked-layer structure example of the semiconductor device 100A. FIG. 15 corresponds to the stacked-layer structure example of the semiconductor device 100A shown in FIG. 11 in the above embodiment.

FIG. 15 shows a transistor 400 as an example of a transistor included in the first circuit 110 or the third circuit 130. The transistor 400 is provided on a substrate 311 and includes a conductive layer 316 functioning as a gate, an insulating layer 315 functioning as a gate insulating layer, a semiconductor region 313 formed of part of the substrate 311, and a low-resistance region 314a and a low-resistance region 314b functioning as a source region and a drain region. As the transistor 400, either a p-channel transistor or an n-channel transistor can be used. As the substrate 311, a single crystal silicon substrate can be used, for example.

In the transistor 400 shown in FIG. 15, the semiconductor region 313 (part of the substrate 311) in which a channel is formed has a protruding shape. In addition, the conductive layer 316 is provided to cover the side surface and the top surface of the semiconductor region 313 with the insulating layer 315 therebetween. Note that a material adjusting the work function may be used for the conductive layer 316. The transistor 400 as described above is also referred to as a FIN-type transistor because it utilizes a protruding portion of a semiconductor substrate. Note that an insulating layer functioning as a mask for forming the protruding portion may be included in contact with an upper portion of the protruding portion. Although the case where the protruding portion is formed by processing part of the semiconductor substrate is described here, a semiconductor film having a protruding shape may be formed by processing an SOI (Silicon On Insulator) substrate.

Note that the transistor 400 shown in FIG. 15 is an example and the structure is not limited thereto; an appropriate transistor is used in accordance with a circuit structure or a driving method.

Wiring layers each provided with an interlayer film, a wiring, a plug, and the like may be provided in the layer 10 and the layer 20. A plurality of wiring layers can be provided in accordance with design. In this specification and the like, a wiring and a plug electrically connected to the wiring may be a single component. That is, part of a conductive layer functions as a wiring in some cases and part of a conductive layer functions as a plug in other cases.

For example, an insulating layer 320, an insulating layer 322, an insulating layer 324, and an insulating layer 326 are sequentially stacked in the layer 10 as interlayer films. A conductive layer 328 and a conductive layer 330 are embedded in the insulating layer 320, the insulating layer 322, the insulating layer 324, and the insulating layer 326. Note that the conductive layer 328 and the conductive layer 330 function as a contact plug or a wiring.

The insulating layers functioning as interlayer films may also function as planarization films that cover uneven shapes therebelow. For example, the top surface of the insulating layer 322 may be subjected to CMP treatment or the like to have improved planarity.

A wiring layer may be provided over the insulating layer 326 and the conductive layer 330. For example, in FIG. 15, an insulating layer 350, an insulating layer 382, and an insulating layer 384 are stacked sequentially over the insulating layer 326 and the conductive layer 330. A conductive layer 386 is formed in the insulating layer 350, the insulating layer 382, and the insulating layer 384. The conductive layer 386 functions as a contact plug or a wiring.

FIG. 15 shows an example of the transistor 121 and the capacitor 122 included in the second circuit 120 formed in the layer 20. FIG. 15 shows an example in which the transistor 751 described in the above embodiment is used as the transistor 121. The description of the structure of the transistor 751 is omitted to reduce repeated description.

In FIG. 15, a conductive layer 368 is embedded in the insulating layer 281, the insulating layer 274, the insulating layer 280, the insulating layer 254, the insulating layer 222, the insulating layer 216, and the insulating layer 214. The conductive layer 368 functions as a contact plug or a wiring. A conductive layer 283, a conductive layer 284, and an insulating layer 282 are provided over the insulating layer 281. The one of the source and the drain of the transistor 121 is electrically connected to the conductive layer 386 through the conductive layer 283, the conductive layer 368, and the like.

An insulating layer 285 is provided over the conductive layer 283, the conductive layer 284, and the insulating layer 282. A conductive layer 287 and an insulating layer 286 are provided over the insulating layer 285. A region where the conductive layer 284, the insulating layer 285, and the conductive layer 287 overlap with each other functions as the capacitor 122.

A conductive layer 289 and an insulating layer 288 are provided over the conductive layer 287 and the insulating layer 286. A conductive layer 292 and an insulating layer 291 are provided over the conductive layer 289 and the insulating layer 288. An insulating layer 293 is provided over the conductive layer 292 and the insulating layer 291.

When the transistor 400 and the transistor 121 are provided to overlap with each other, the area occupied by the semiconductor device 100A can be reduced. When the transistor 400 and the transistor 121 are provided to overlap with each other, the length of a wiring electrically connecting the transistor 400 and the transistor 121 can be shortened. Thus, the parasitic capacitance and wiring resistance accompanying the wiring are reduced, so that the power consumption of the semiconductor device 100A can be reduced. Furthermore, the signal transmission distance is shortened, so that the operation speed of the semiconductor device 100A can be increased.

The structure described in this embodiment can be used in an appropriate combination with the structures described in the other embodiments.

### EMBODIMENT 4

In this embodiment, an example of an arithmetic processing device that can include the semiconductor device of one embodiment of the present invention will be described.

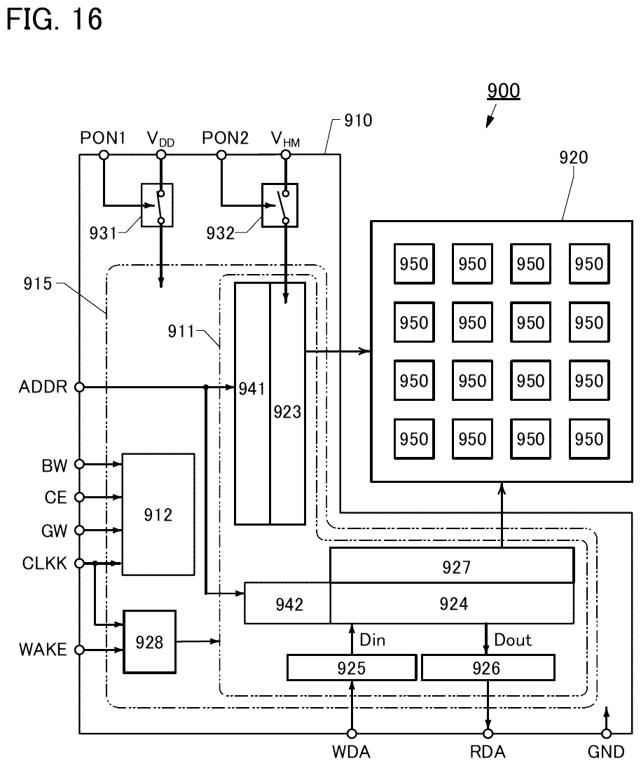

FIG. 16 shows a block diagram showing a structure example of a semiconductor device 900. The semiconductor device 900 shown in FIG. 16 includes a driver circuit 910 and a memory array 920. The memory array 920 includes at least one memory cell 950. FIG. 16 shows an example in which the memory array 920 includes a plurality of memory cells 950 arranged in a matrix.

The semiconductor device 100 (the semiconductor device 100A, the semiconductor device 100B, the semiconductor device 100C, and the semiconductor device 100D) described as an example in the above embodiment can be used for the memory cell 950. The driver circuit 910 is provided in the layer 10 shown in FIG. 11, for example.

The driver circuit 910 includes a PSW 931 (power switch), a PSW 932, and a peripheral circuit 915. The peripheral circuit 915 includes a peripheral circuit 911, a control circuit 912, and a voltage generation circuit 928.

In the semiconductor device 900, the circuits, signals, and voltages can be appropriately selected as needed. Alternatively, another circuit or another signal may be added. A signal BW, a signal CE, a signal GW, a signal CLKK, a signal WAKE, a signal ADDR, a signal WDA, a signal PON1, and a signal PON2 are signals input from the outside, and a signal RDA is a signal output to the outside. The signal CLKK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 912.

The control circuit 912 is a logic circuit having a function of controlling the overall operation of the semiconductor device 900. For example, the control circuit 912 performs logical operation on the signal CE, the signal GW, and the signal BW to determine an operation mode of the semiconductor device 900 (e.g., write operation or read operation). Alternatively, the control circuit 912 generates a control signal for the peripheral circuit 911 so that the operation mode is executed.

The voltage generation circuit 928 has a function of generating negative voltage. The signal WAKE has a function of controlling the input of the signal CLKK to the voltage generation circuit 928. For example, when an H-level signal is applied as the signal WAKE, the signal CLKK is input to the voltage generation circuit 928, and the voltage generation circuit 928 generates negative voltage.

The peripheral circuit 911 is a circuit for writing and reading data to/from the memory cell 950. The peripheral circuit 911 includes a row decoder 941, a column decoder 942, a row driver 923, a column driver 924, an input circuit 925, an output circuit 926, and a sense amplifier 927.

The row decoder 941 and the column decoder 942 have a function of decoding the signal ADDR. The row decoder 941 is a circuit for specifying a row to be accessed, and the column decoder 942 is a circuit for specifying a column to be accessed. The row driver 923 has a function of selecting the row specified by the row decoder 941. The column driver 924 has a function of writing data to the memory cell 950, a function of reading data from the memory cell 950, a function of retaining the read data, and the like.

The input circuit 925 has a function of retaining the signal WDA. Data retained in the input circuit 925 is output to the column driver 924. Data output from the input circuit 925 is data (Din) to be written to the memory cell 950. Data (Dout) read from the memory cell 950 by the column driver 924 is output to the output circuit 926. The output circuit 926 has a function of retaining Dout. In addition, the output circuit 926 has a function of outputting Dout to the outside of the semiconductor device 900. Data output from the output circuit 926 is the signal RDA.

The PSW 931 has a function of controlling the supply of VDD to the peripheral circuit 915. The PSW 932 has a function of controlling the supply of VHM to the row driver 923. Here, in the semiconductor device 900, a high power supply potential is VDD and a low power supply potential is GND (ground potential). In addition, VHM is a high power supply potential used to set a word line at a high level and is higher than VDD. The on/off state of the PSW 931 is controlled by the signal PON1, and the on/off state of the PSW 932 is controlled by the signal PON2. The number of power domains to which VDD is supplied is one in the peripheral circuit 915 in FIG. 16 but can be more than one. In that case, a power switch is provided for each power domain.

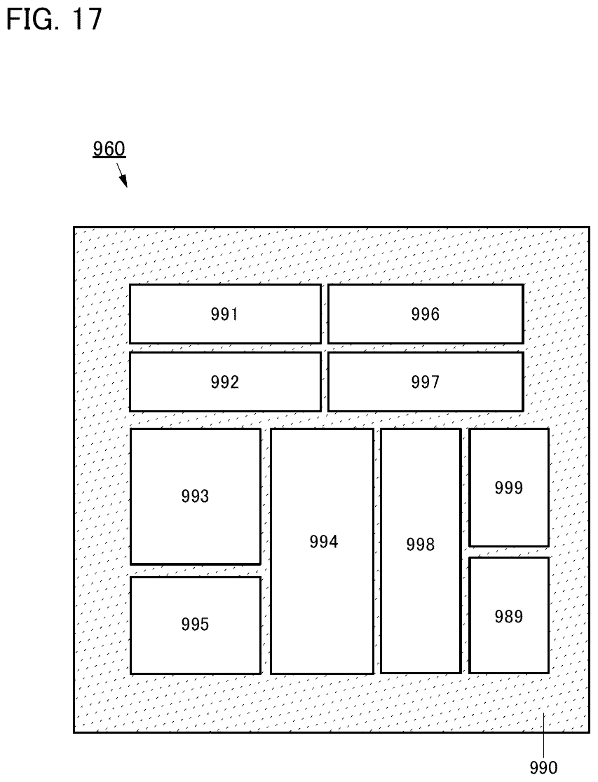

FIG. 17 shows a block diagram of an arithmetic device 960. The arithmetic device 960 shown in FIG. 17 can be used for a CPU (Central Processing Unit), for example. The arithmetic device 960 can also be used for a processor including a larger number of (several tens to several hundreds of) processor cores capable of parallel processing than a CPU, such as a GPU (Graphics Processing Unit), a TPU (Tensor Processing Unit), or an NPU (Neural Processing Unit).

The arithmetic device 960 shown in FIG. 17 includes, over a substrate 990, an ALU 991 (Arithmetic logic unit, arithmetic circuit), an ALU controller 992, an instruction decoder 993, an interrupt controller 994, a timing controller 995, a register 996, a register controller 997, a bus interface 998, a cache memory 999, and a cache interface 989. A semiconductor substrate, an SOI substrate, a glass substrate, or the like is used as the substrate 990. The arithmetic device 960 may include a rewritable ROM and a ROM interface. In addition, the cache memory 999 and the cache interface 989 may be provided in a separate chip. The semiconductor device 100 can be used for the register 996.

The cache memory 999 is connected via the cache interface 989 to a main memory provided in another chip. The cache interface 989 has a function of supplying part of data retained in the main memory to the cache memory 999. The cache interface 989 also has a function of outputting part of data retained in the cache memory 999 to the ALU 991, the register 996, or the like through the bus interface 998.

As described later, the memory array 920 can be stacked over the arithmetic device 960. The memory array 920 can be used as a cache. Here, the cache interface 989 may have a function of supplying data retained in the memory array 920 to the cache memory 999.

Note that it is also possible that the cache memory 999 is not provided and only the memory array 920 is used as a cache memory (also referred to as a “cache”).

The arithmetic device 960 shown in FIG. 17 is only an example with a simplified structure, and the actual arithmetic device 960 has a variety of structures depending on the application. For example, what is called a multicore structure is preferably employed in which a plurality of cores each including the arithmetic device 960 shown in FIG. 17 operate in parallel. The larger number of cores can further enhance the arithmetic performance. The number of cores is preferably larger; for example, the number is preferably 2, further preferably 4, still further preferably 8, yet still further preferably 12, yet still further preferably 16 or larger. For application requiring extremely high arithmetic performance, e.g., a server, it is preferable to employ the multicore structure including 16 or more, preferably 32 or more, further preferably 64 or more cores. The number of bits that the arithmetic device 960 can process in an internal arithmetic circuit or in a data bus can be 8, 16, 32, or 64, for example.

An instruction that is input to the arithmetic device 960 through the bus interface 998 is input to the instruction decoder 993 and decoded therein, and then, input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. While the arithmetic device 960 is executing a program, the interrupt controller 994 judges an interrupt request from an external input/output device, a peripheral circuit, or the like on the basis of its priority or a mask state, and processes the request. The register controller 997 generates an address of the register 996, and reads/writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above various circuits.

In the arithmetic device 960 shown in FIG. 17, the register controller 997 selects a retention operation in the register 996 in accordance with an instruction from the ALU 991. That is, the register controller 997 selects whether data is stored by a flip-flop or by a capacitor in the memory cell included in the register 996. When data storing by the flip-flop is selected, a power supply potential is supplied to the memory cell in the register 996. When data storing by the capacitor is selected, the data is rewritten in the capacitor, and supply of the power supply potential to the memory cell in the register 996 can be stopped.

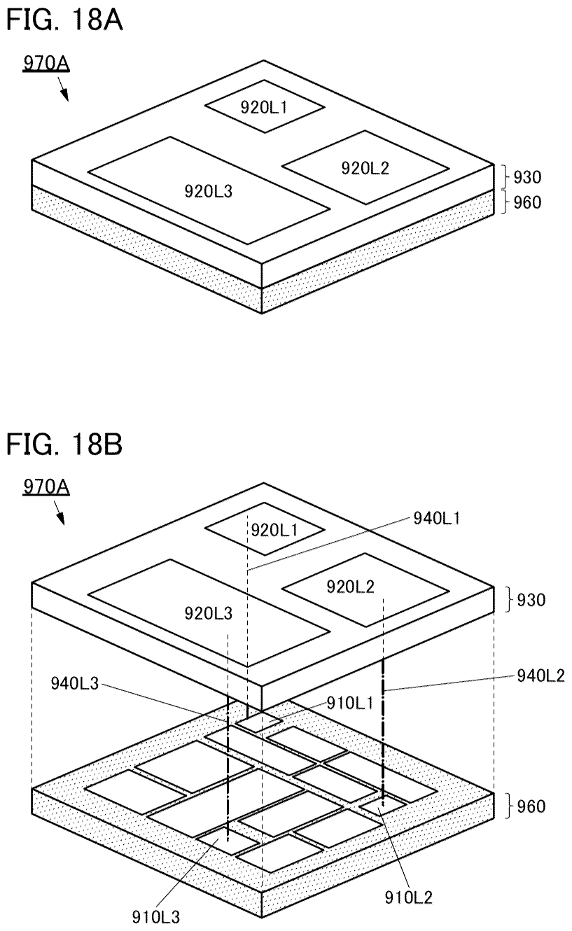

The memory array 920 and the arithmetic device 960 can be provided to overlap with each other. FIG. 18A and FIG. 18B show perspective views of a semiconductor device 970A. The semiconductor device 970A includes a layer 930 provided with the memory arrays 920 over the arithmetic device 960. In FIG. 18A and FIG. 18B, a memory array 920L1, a memory array 920L2, and a memory array 920L3 are shown as the memory array 920. The memory array 920L1, the memory array 920L2, and the memory array 920L3 are provided in the layer 930. The arithmetic device 960 and each of the memory arrays 920 include overlap regions. For easy understanding of the structure of the semiconductor device 970A, the arithmetic device 960 and the layer 930 are separately shown in FIG. 18B.

Providing the layer 930 including the memory arrays 920 and the arithmetic device 960 to overlap with each other can shorten the connection distance therebetween. Accordingly, the communication speed therebetween can be increased. Moreover, since the connection distance is short, power consumption can be reduced.

As a method for stacking the layer 930 including the memory arrays 920 and the arithmetic device 960, either of the following methods may be employed: a method in which the layer 930 including the memory arrays 920 is stacked directly on the arithmetic device 960 (also referred to as monolithic stacking) and a method in which the arithmetic device 960 and the layer 930 are formed over different substrates, the two substrates are bonded to each other, and the arithmetic device 960 and the layer 930 are electrically connected to each other using a through via or a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache memory 999 and the memory arrays 920L1, 920L2, and 920L3 provided in the layer 930 are each used as a cache memory. In that case, for example, the memory array 920L1 can be used as an L1 cache (also referred to as a level 1 cache), the memory array 920L2 can be used as an L2 cache (also referred to as a level 2 cache), and the memory array 920L3 can be used as an L3 cache (also referred to as a level 3 cache). Among the three memory arrays, the memory array 920L3 has the highest storage capacity and the lowest access frequency. The memory array 920L1 has the lowest capacity and the highest access frequency.

Note that in the case where the cache memory 999 provided in the arithmetic device 960 is used as the L1 cache, the memory arrays provided in the layer 930 can each be used as the lower-level cache or the main memory. The main memory has higher storage capacity and lower access frequency than the cache.

As shown in FIG. 18B, the arithmetic device 960 may be provided with a driver circuit 910L1, a driver circuit 910L2, and a driver circuit 910L3. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Although three memory arrays functioning as cache memories are shown here, the number of memory arrays functioning as cache memories can be one or two. Alternatively, the number of memory arrays functioning as cache memories can be four or more.

In the case where the memory array 920L1 is used as a cache, the driver circuit 910L1 may function as part of the cache interface 989 or the driver circuit 910L1 may be connected to the cache interface 989. Similarly, each of the driver circuit 910L2 and the driver circuit 910L3 may function as part of the cache interface 989 or be connected thereto.

Whether the memory array 920 functions as the cache or the main memory is determined by the control circuit 912 included in each of the driver circuits 910. The control circuit 912 can make some of the plurality of memory cells 950 included in the semiconductor device 900 function as RAM in accordance with a signal supplied from the arithmetic device 960.

In the semiconductor device 900, some of the plurality of memory cells 950 can function as the caches and the other memory cells 950 can function as the main memory. That is, the semiconductor device 900 can have both the function of the cache and the function of the main memory. The semiconductor device 900 of one embodiment of the present invention can function as a universal memory, for example.

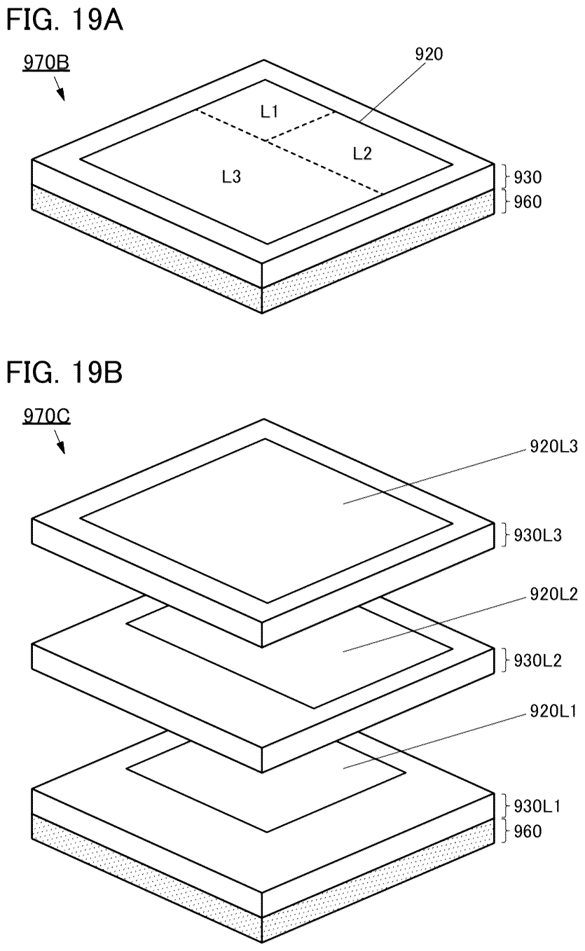

The layer 930 including one memory array 920 may be provided to overlap with the arithmetic device 960. FIG. 19A shows a perspective view of a semiconductor device 970B.

In the semiconductor device 970B, one memory array 920 can be divided into a plurality of areas having different functions. FIG. 19A shows an example in which a region L1, a region L2, and a region L3 are used as the L1 cache, the L2 cache, and the L3 cache, respectively.

In the semiconductor device 970B, the capacity of each of the region L1 to the region L3can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 19B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the farthest memory array 920L3 can be used as a low-level cache or a main memory. Such a structure can increase the capacity of each memory array, thereby improving processing capability.

The structure described in this embodiment can be used in an appropriate combination with the structures described in the other embodiments.

### EMBODIMENT 5

In this embodiment, application examples of the storage device of one embodiment of the present invention will be described.

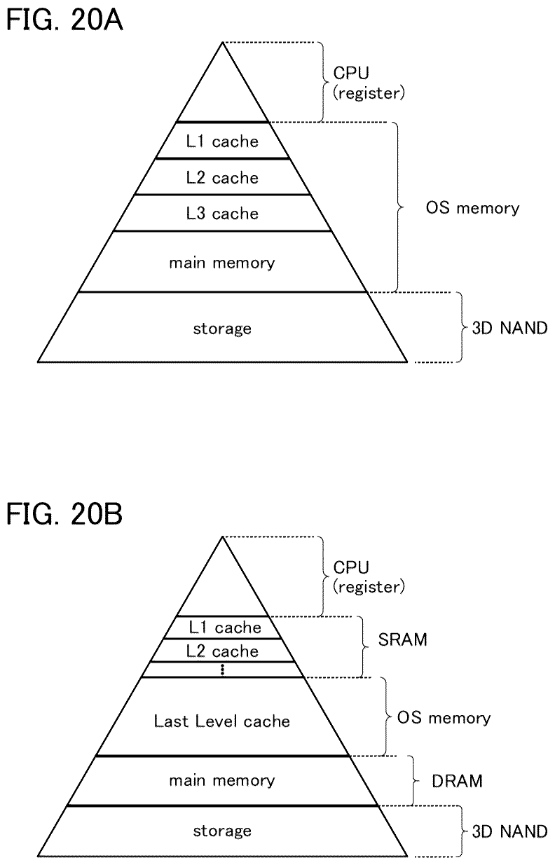

In general, a variety of storage devices are used in semiconductor devices such as computers in accordance with the intended use. FIG. 20A shows the hierarchy of various storage devices used in a semiconductor device. The storage devices at the upper levels require a higher operating speed, whereas the storage devices at the lower levels require a larger storage capacity and a higher memory density. In FIG. 20A, sequentially from the top level, a memory included as a register in an arithmetic processing device such as a CPU, the L1 cache, the L2 cache, the L3 cache, a main memory, a storage, and the like are shown. Although an example including the caches up to the L3 cache is described here, a lower-level cache may further be included.

A memory included as a register in an arithmetic processing unit such as a CPU is used for temporary storage of arithmetic operation results, for example, and thus is frequently accessed by the arithmetic processing unit. Accordingly, high operation speed is required rather than storage capacity. In addition, the register also has a function of retaining settings information of the arithmetic processing unit, for example. For the register, the semiconductor device 100 of one embodiment of the present invention can be used.

The cache has a function of duplicating and retaining part of data retained in a main memory. Duplicating frequently used data and retaining the duplicated data in the cache facilitates rapid data access. The cache requires a smaller storage capacity than the main memory but a higher operating speed than the main memory. Data that is rewritten in the cache is duplicated, and the duplicated data is supplied to the main memory.

The main memory has a function of retaining a program, data, and the like that are read from the storage.

The storage has a function of retaining data that needs to be retained for a long time and programs used in an arithmetic processing device, for example. Therefore, a storage needs to have high storage capacity and high memory density rather than operating speed. For example, a high-capacity nonvolatile storage device such as a 3D NAND can be used.

The semiconductor device 100 of one embodiment of the present invention operates at high speed and can retain data for a long time. Thus, as shown in FIG. 20A, the storage device of one embodiment of the present invention is suitable for both the level where the cache is positioned and the level where the main memory is positioned. The storage device of one embodiment of the present invention can also be used at the level where the storage is positioned.

FIG. 20B shows an example in which an SRAM is used as some caches and the OS memory of one embodiment of the present invention is used as the other cache.

Among the caches, the lowest-level cache can be referred to as an LLC (Last Level cache). The LLC does not require a higher operating speed than a higher-level cache, but desirably has a large storage capacity. The semiconductor device 100 of one embodiment of the present invention operates at high speed and can retain data for a long time, and thus is suitable as the LLC. Note that the semiconductor device 100 of one embodiment of the present invention can also be used as an FLC (Final Level cache).

For example, as shown in FIG. 20B, an SRAM can be used as the higher-level caches (the L1 cache, the L2 cache, and the like), and the semiconductor device 100 of one embodiment of the present invention may be used as the LLC. Moreover, in addition to the OS memory, a DRAM can also be used as the main memory as shown in FIG. 20B.

The structure described in this embodiment can be used in an appropriate combination with the structures described in the other embodiments.

### EMBODIMENT 6

In this embodiment, application examples of the semiconductor device of one embodiment of the present invention will be described.

The semiconductor device according to one embodiment of the present invention can be used for a variety of electronic components. For example, the semiconductor device can be applied to a register of a microprocessor such as a DSP (Digital Signal Processor) or a GPU (Graphics Processing Unit) or a cache memory. The microprocessor may be constructed with a PLD (Programmable Logic Device) such as an FPGA (Field Programmable Gate Array) or an FPAA (Field Programmable Analog Array).

Thus, the semiconductor device of one embodiment of the present invention can be applied to, for example, a variety of electronic devices (e.g., information terminals, computers, smartphones, e-book readers, digital still cameras, video cameras, video recording/reproducing devices, navigation systems, game machines, and the like). In addition, the semiconductor device can also be used for image sensors, IoT (Internet of Things), healthcare-related devices, and the like. Note that here, the computers refer not only to tablet computers, laptop computers, and desktop computers, but also to large computers such as server systems.

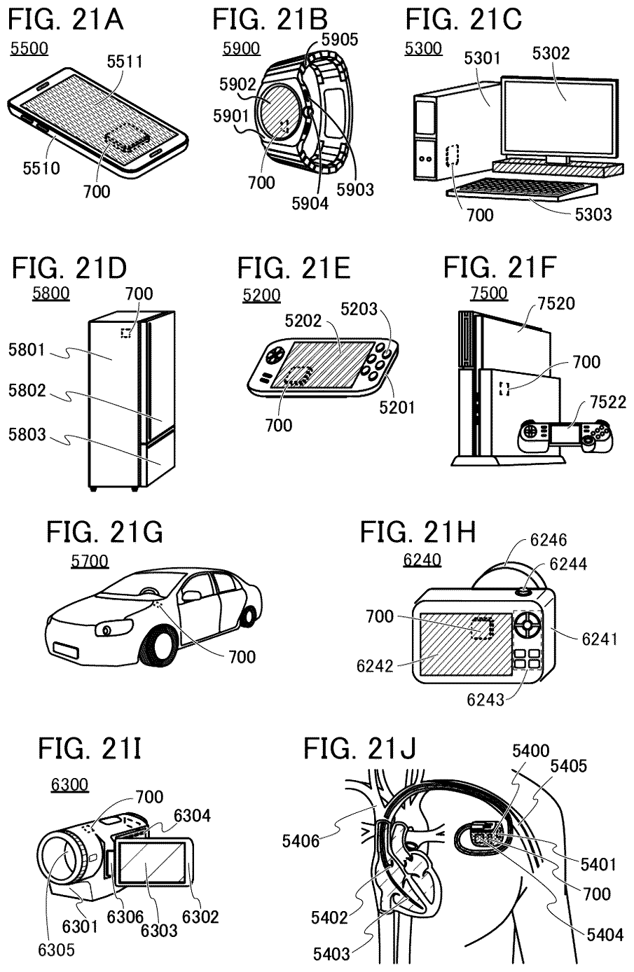

An example of an electronic device including the semiconductor device of one embodiment of the present invention is described. Note that FIG. 21A to FIG. 21J each show a state where an electronic component 700 including the semiconductor device is included in an electronic device.

### [Mobile Phone]

An information terminal 5500 shown in FIG. 21A is a mobile phone (smartphone), which is a type of information terminal. The information terminal 5500 includes a housing 5510 and a display portion 5511, and as input interfaces, a touch panel is provided in the display portion 5511 and a button is provided in the housing 5510.

With use of the semiconductor device of one embodiment of the present invention, the information terminal 5500 with reduced power consumption can be achieved. Thus, the usage time of the information terminal 5500 can be extended. Owing to the reduced power consumption, heat generation from a circuit can be reduced; thus, adverse effects on the circuit itself, a peripheral circuit, and a module can be reduced. Thus, the reliability of the information terminal 5500 can be improved.

### [Wearable Terminal]

FIG. 21B shows an information terminal 5900 that is an example of a wearable terminal. The information terminal 5900 includes a housing 5901, a display portion 5902, an operation switch 5903, an operation switch 5904, a band 5905, and the like.

With use of the semiconductor device of one embodiment of the present invention, the information terminal 5900 with reduced power consumption can be achieved. Thus, the usage time of the information terminal 5900 can be extended. Owing to the reduced power consumption, heat generation from a circuit can be reduced; thus, adverse effects on the circuit itself, a peripheral circuit, and a module can be reduced. Thus, the reliability of the information terminal 5900 can be improved.

### [Information Terminal]

FIG. 21C shows a desktop information terminal 5300. The desktop information terminal 5300 includes a main body 5301 of the information terminal, a display portion 5302, and a keyboard 5303.

With use of the semiconductor device of one embodiment of the present invention, the desktop information terminal 5300 with reduced power consumption can be achieved. Owing to the reduced power consumption, heat generation from a circuit can be reduced; thus, adverse effects on the circuit itself, a peripheral circuit, and a module can be reduced. Thus, the reliability of the desktop information terminal 5300 can be improved.

Note that although the smartphone, the wearable terminal, and the desktop information terminal are respectively shown in FIG. 21A to FIG. 21C as examples of the electronic device, one embodiment of the present invention can be applied to an information terminal other than a smartphone, a wearable terminal, and a desktop information terminal. Examples of information terminals other than a smartphone, a wearable terminal, and a desktop information terminal include a PDA (Personal Digital Assistant), a laptop information terminal, and a workstation.

### [Household Appliance]

FIG. 21D shows an electric refrigerator-freezer 5800 as an example of a household appliance. The electric refrigerator-freezer 5800 includes a housing 5801, a refrigerator door 5802, a freezer door 5803, and the like. For example, the electric refrigerator-freezer 5800 is an electric refrigerator-freezer that is compatible with IoT (Internet of Things).

The semiconductor device of one embodiment of the present invention can be applied to the electric refrigerator-freezer 5800. The electric refrigerator-freezer 5800 can transmit and receive information on food stored in the electric refrigerator-freezer 5800 and food expiration dates, for example, to and from an information terminal or the like via the Internet or the like.

With use of the semiconductor device of one embodiment of the present invention, the electric refrigerator-freezer 5800 with reduced power consumption can be achieved. Owing to the reduced power consumption, heat generation from a circuit can be reduced; thus, adverse effects on the circuit itself, a peripheral circuit, and a module can be reduced. Thus, the reliability of the electric refrigerator-freezer 5800 can be improved.

Although the electric refrigerator-freezer is described in this example as a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audiovisual appliance.

[Game machine]

FIG. 21E shows a portable game machine 5200 as an example of a game machine. The portable game machine 5200 includes a housing 5201, a display portion 5202, a button 5203, and the like.

In addition, FIG. 21F shows a stationary game machine 7500 as another example of a game machine. The stationary game machine 7500 includes a main body 7520 and a controller 7522. Note that the controller 7522 can be connected to the main body 7520 with or without a wire. Although not shown in FIG. 21F, the controller 7522 can include a display portion that displays a game image, and an input interface besides a button, such as a touch panel, a stick, a rotating knob, or a sliding knob, for example. The shape of the controller 7522 is not limited to that shown in FIG. 21F, and the shape of the controller 7522 may be changed in various ways in accordance with the genres of games. For example, for a shooting game such as an FPS (First Person Shooter) game, a gun-shaped controller having a trigger button can be used. As another example, for a music game or the like, a controller having a shape of a musical instrument, audio equipment, or the like can be used. Furthermore, the stationary game machine may include a camera, a depth sensor, a microphone, and the like so that the game player can play a game using a gesture or a voice instead of a controller.

In addition, videos displayed on the game machine can be output with a display device such as a television device, a personal computer display, a game display, or a head-mounted display.

With use of the semiconductor device of one embodiment of the present invention for the portable game machine 5200 or the stationary game machine 7500, the portable game machine 5200 with reduced power consumption or the stationary game machine 7500 with reduced power consumption can be achieved. Thus, the usage time of the portable game machine 5200 can be extended. Owing to the reduced power consumption, heat generation from a circuit can be reduced; thus, adverse effects on the circuit itself, a peripheral circuit, and a module can be reduced. Thus, the reliability of the portable game machine 5200 and the stationary game machine 7500 can be improved.

As an example of a game machine, FIG. 21E shows a portable game machine. In addition, FIG. 21F shows a home-use stationary game machine. Note that an electronic device of one embodiment of the present invention is not limited thereto. Examples of the electronic device of one embodiment of the present invention include an arcade game machine installed in entertainment facilities (a game center, an amusement park, and the like), and a throwing machine for batting practice installed in sports facilities.

### [Moving Vehicle]

The semiconductor device described in the above embodiment can be used for an automobile, which is a moving vehicle, and around the driver's seat in an automobile.

FIG. 21G shows an automobile 5700, which is an example of a moving vehicle.

An instrument panel that can display a speedometer, a tachometer, a mileage, a fuel meter, a gearshift state, air-conditioning setting, or the like is provided around the driver's seat in the automobile 5700. In addition, a display device showing the above information may be provided around the driver's seat.

In particular, the display device can compensate for the view obstructed by a pillar or the like, blind areas for the driver's seat, and the like by displaying a video from an imaging device (not shown) provided for the automobile 5700, which can increase safety. That is, display of an image from an imaging device provided on the outside of the automobile 5700 can fill in blind areas and increase safety.

With use of the semiconductor device of one embodiment of the present invention, the moving vehicle with reduced power consumption can be achieved. Owing to the reduced power consumption, heat generation from a circuit can be reduced; thus, adverse effects on the circuit itself, a peripheral circuit, and a module can be reduced. Thus, the reliability of the moving vehicle can be improved.

Note that although an automobile is described above as an example of a moving vehicle, the moving vehicle is not limited to an automobile. Examples of moving vehicles include a train, a monorail train, a ship, and a flying object (a helicopter, an unmanned aircraft (a drone), an airplane, and a rocket).

### [Camera]

The semiconductor device described in the above embodiment can be employed for a camera.

FIG. 21H shows a digital camera 6240 as an example of an imaging device. The digital camera 6240 includes a housing 6241, a display portion 6242, operation switches 6243, a shutter button 6244, and the like, and a detachable lens 6246 is attached to the digital camera 6240. Note that the digital camera 6240 is configured here such that the lens 6246 is detachable from the housing 6241 for replacement; alternatively, the lens 6246 may be integrated with the housing 6241. In addition, the digital camera 6240 may be configured to be additionally equipped with a stroboscope, a viewfinder, or the like.

With use of the semiconductor device of one embodiment of the present invention, the digital camera 6240 with reduced power consumption can be achieved. The imaging time can be extended owing to the reduced power consumption. Owing to the reduced power consumption, heat generation from a circuit can be reduced; thus, adverse effects due to the heat generation on the circuit itself, a peripheral circuit, and a module can be reduced. Thus, the reliability of the digital camera 6240 can be improved.

### [Video Camera]

The semiconductor device described in the above embodiment can be employed for a video camera.

FIG. 21I shows a video camera 6300 as an example of an imaging device. The video camera 6300 includes a first housing 6301, a second housing 6302, a display portion 6303, operation switches 6304, a lens 6305, a joint 6306, and the like. The operation switches 6304 and the lens 6305 are provided in the first housing 6301, and the display portion 6303 is provided in the second housing 6302. The first housing 6301 and the second housing 6302 are connected to each other with the joint 6306, and an angle between the first housing 6301 and the second housing 6302 can be changed with the joint 6306. Images displayed on the display portion 6303 may be changed in accordance with the angle at the joint 6306 between the first housing 6301 and the second housing 6302.

With use of the semiconductor device of one embodiment of the present invention, the video camera 6300 with reduced power consumption can be achieved. The imaging time can be extended owing to the reduced power consumption. Owing to the reduced power consumption, heat generation from a circuit can be reduced; thus, adverse effects due to the heat generation on the circuit itself, a peripheral circuit, and a module can be reduced. Thus, the reliability of the video camera 6300 can be improved.

### [ICD]

The semiconductor device described in the above embodiment can be employed for an implantable cardioverter-defibrillator (ICD).

FIG. 21J is a schematic cross-sectional view showing an example of an ICD. An ICD main unit 5400 includes at least a battery 5401, the electronic component 700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with an end of one of the wires placed in the right ventricle and an end of the other wire placed in the right atrium.

The ICD main unit 5400 functions as a pacemaker and paces the heart when the heart rate is not within a predetermined range. In addition, when the heart rate is not recovered by pacing (e.g., when ventricular tachycardia or ventricular fibrillation occurs), treatment with an electrical shock is performed.

The ICD main unit 5400 needs to monitor the heart rate all the time in order to perform pacing and deliver electrical shocks as appropriate. For that reason, the ICD main unit 5400 includes a sensor for measuring the heart rate. In addition, in the ICD main unit 5400, data on the heart rate obtained by the sensor or the like, the number of times the treatment with pacing is performed, and the time taken for the treatment, for example, can be stored in the electronic component 700.

The antenna 5404 can receive electric power, and the battery 5401 is charged with the electric power. Furthermore, when the ICD main unit 5400 includes a plurality of batteries, safety can be increased. Specifically, even when some of the batteries in the ICD main unit 5400 are dead, the other batteries can work properly; thus, the batteries also function as an auxiliary power source.

In addition to the antenna 5404 capable of receiving power, an antenna that can transmit physiological signals may be included to construct, for example, a system that monitors cardiac activity by checking physiological signals such as a pulse, a respiratory rate, a heart rate, and body temperature with an external monitoring device.

With use of the semiconductor device of one embodiment of the present invention, the ICD main unit 5400 with reduced power consumption can be achieved. The size and weight of a storage battery can be reduced owing to the reduced power consumption. Owing to the reduced power consumption, heat generation of the ICD main unit 5400 can be reduced; thus, a load on the human body can be reduced. Furthermore, the reliability of the ICD main unit 5400 can be improved.

### [Computer]

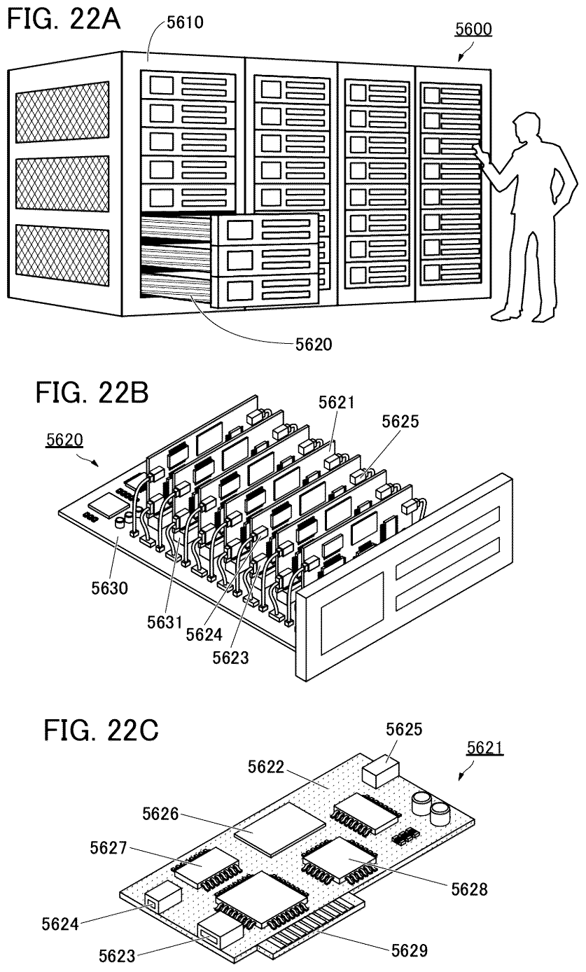

A computer 5600 shown in FIG. 22A is an example of a large computer (a supercomputer) mainly used for scientific computation. In scientific computation, an enormous amount of arithmetic operation needs to be processed at high speed; hence, power consumption is high and chips generate a large amount of heat. For example, a data center including a plurality of super computers uses an enormous amount of digital data. Specifically, the amount of digital data in the world is expected to exceed 1024 (yotta) bytes or 1030 (quetta) bytes.

With use of the semiconductor device of one embodiment of the present invention, a supercomputer with reduced power consumption can be achieved. Owing to the reduced power consumption, heat generation from a circuit can be reduced; thus, adverse effects due to the heat generation on the circuit itself, a peripheral circuit, and a module are reduced. When the semiconductor device of one embodiment of the present invention is used, the supercomputer with reduced power consumption can be achieved. This is expected to greatly contribute to global warming countermeasures.

In the computer 5600, a plurality of rack mount computers 5620 are stored in a rack 5610. The computer 5620 can have a structure in a perspective view shown in FIG. 22B, for example. In FIG. 22B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 shown in FIG. 22C is an example of a processing board provided with a CPU, a GPU, a storage device, and the like. The PC card 5621 includes a board 5622. In addition, the board 5622 includes the connection terminal 5623, the connection terminal 5624, the connection terminal 5625, a semiconductor device 5626, a semiconductor device 5627, a semiconductor device 5628, and a connection terminal 5629. Note that FIG. 22C also shows semiconductor devices other than the semiconductor device 5626, the semiconductor device 5627, and the semiconductor device 5628, and the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not shown) for inputting and outputting signals, and when the terminal is inserted in a socket (not shown) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA (Field Programmable Gate Array), a GPU, and a CPU. As the semiconductor device 5627, the electronic component 700 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a storage device.

The computer 5600 can also function as a parallel computer. When the computer 5600 is used as a parallel computer, large-scale computation necessary for artificial intelligence learning and inference can be performed, for example.

With use of the semiconductor device of one embodiment of the present invention, a reduction in power consumption of the electronic device can be achieved. Owing to the reduced power consumption, heat generation from a circuit can be reduced; thus, adverse effects on the circuit itself, a peripheral circuit, and a module can be reduced. Furthermore, the use of the semiconductor device of one embodiment of the present invention can achieve an electronic device that operates stably even in a high temperature environment. Thus, the reliability of the electronic device can be improved.

The structure described in this embodiment can be used in an appropriate combination with the structures described in the other embodiments.

### EMBODIMENT 7

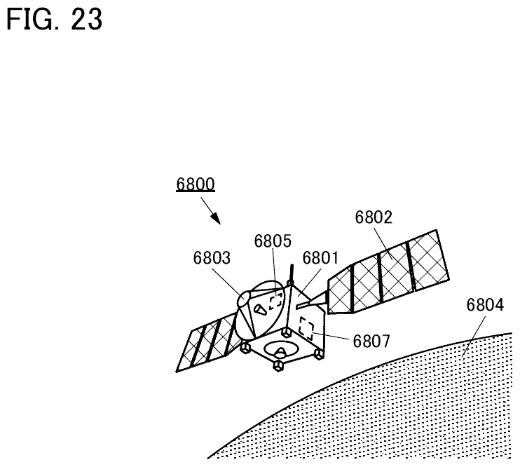

The semiconductor device of one embodiment of the present invention includes an OS transistor. A change in electrical characteristics of the OS transistor due to radiation irradiation is small. That is, the OS transistor is highly resistant to radiation, and thus is suitable in an environment where radiation can enter. For example, OS transistors are be suitably used in outer space. In this embodiment, a specific example of using the semiconductor device of one embodiment of the present invention in a device for space will be described with reference to FIG. 23.

FIG. 23 shows an artificial satellite 6800 as an example of a device for space. The artificial satellite 6800 includes a body 6801, a solar panel 6802, an antenna 6803, a secondary battery 6805, and a control device 6807. In FIG. 23, a planet 6804 in outer space is shown as an example. Note that outer space refers to, for example, space at an altitude greater than or equal to 100 km, and outer space described in this specification includes thermosphere, mesosphere, and stratosphere in some cases.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a storage device, for example. Note that the semiconductor device that is one embodiment of the present invention and includes an OS transistor is suitably used for the control device 6807. A change in electrical characteristics due to radiation irradiation is smaller in an OS transistor than in a Si transistor. That is, the OS transistor has high reliability and thus is suitable even in an environment where radiation can enter.

The artificial satellite 6800 can be configured to include a sensor. For example, when configured to include a visible light sensor, the artificial satellite 6800 can have a function of sensing sunlight reflected by a ground-based object. Alternatively, when configured to include a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of a device for space in this embodiment, one embodiment of the present invention is not limited thereto. The semiconductor device of one embodiment of the present invention is suitable for a device for space such as a spacecraft, a space capsule, or a space probe, for example.

The structure described in this embodiment can be used in an appropriate combination with the structures described in the other embodiments.

### REFERENCE NUMERALS

100: semiconductor device, 110: first circuit, 111: first inverter circuit, 112: first switch, 113: second switch, 114: second inverter circuit, 115: third switch, 116: third inverter circuit, 117: fourth switch, 118: fourth inverter circuit, 119: fifth inverter circuit, 120: second circuit, 121: transistor, 122: capacitor, 130: third circuit, 131: inverter circuit, 132: first AND circuit, 133: second AND circuit, 134: NOR circuit, 141: inverter circuit, 151: latch circuit, 152: latch circuit, 156: NAND circuit, 157: NAND circuit, 159: transistor, 160: edge detection circuit, 161: inverter circuit, 162: AND circuit, 163: resistor, 164: capacitor, 165: delay circuit

1. A semiconductor device comprising:
a first circuit;
a second circuit; and
a third circuit,
wherein the first circuit comprises a first inverter circuit, a second inverter circuit, a third inverter circuit, a fourth inverter circuit, and a fifth inverter circuit and a first switch, a second switch, a third switch, and a fourth switch,
wherein the second circuit comprises an input portion X and an output portion Y,
wherein the third circuit comprises an input portion A, an input portion B, and an output portion Z,
wherein an output portion of the first inverter circuit is electrically connected to one terminal of the first switch,
wherein the other terminal of the first switch is electrically connected to one terminal of the second switch,
wherein the other terminal of the second switch is electrically connected to an output portion of the second inverter circuit,
wherein an input portion of the second inverter circuit is electrically connected to one terminal of the third switch,
wherein the other terminal of the third switch is electrically connected to an input portion of the third inverter circuit and one terminal of the fourth switch,
wherein an output portion of the third inverter circuit is electrically connected to an input portion of the fourth inverter circuit and an input portion of the fifth inverter circuit,
wherein an output portion of the fourth inverter circuit is electrically connected to the other terminal of the fourth switch,
wherein the output portion of the third inverter circuit is electrically connected to the input portion X,
wherein the output portion Y is electrically connected to the input portion A,
wherein the input portion B is electrically connected to the one terminal of the second switch, and
wherein the output portion Z is electrically connected to the one terminal of the third switch.

2. The semiconductor device according to claim 1,
wherein the second circuit comprises a transistor and a capacitor,
wherein one of a source and a drain of the transistor functions as the input portion X,
wherein the other of the source and the drain of the transistor functions as the output portion Y, and
wherein the other of the source and the drain of the transistor is electrically connected to one terminal of the capacitor.

3. The semiconductor device according to claim 2,
wherein the transistor comprises an oxide semiconductor in a semiconductor layer where a channel is formed.

4. The semiconductor device according to claim 1 is configured to supply, to an output portion of the fifth inverter circuit, a signal corresponding to a signal supplied to an input portion of the first inverter circuit, in synchronization with a clock signal.

5. The semiconductor device according to claim 1,
wherein each of the first switch and the fourth switch is configured to operate in synchronization with a clock signal, and each of the second switch and the third switch has a function of operating is configured to operate in synchronization with an inverted clock signal.

6. The semiconductor device according to claim 1,
wherein the third circuit has is configured to:
supply, to the output portion Z, a signal corresponding to a signal supplied to the input portion A;
supply, to the output portion Z, a signal corresponding to a signal supplied to the input portion B; and
determine a signal to be supplied to the output portion Z in accordance with a selection signal.
